(19) United States
(12) Patent Application Publication
(10) Pub. No.: US 2026/0082636 A1
(43) Pub. Date: Mar. 19, 2026

(54) SEMICONDUCTOR STORAGE DEVICE AND SEMICONDUCTOR DEVICE

(71) Applicant: Kioxia Corporation, Tokyo (JP)

(72) Inventors: Mikiya ISHII, Yokkaichi Mie (JP); Masayuki MURASE, Yokkaichi Mie (JP); Yuya MATSUZAWA, Yokkaichi Mie (JP); Shosuke FUJII, Kuwana Mie (JP); Kotaro NODA, Yokkaichi Mie (JP)

(21) Appl. No.: 19/069,087

(22) Filed: Mar. 3, 2025

(30) Foreign Application Priority Data
Sep. 13, 2024 (JP) 2024-158967

(51) Int. Cl. H10D 30/67; H10B 12/00

(52) U.S. Cl. CPC H10D 30/6755; H10B 12/03; H10B 12/05; H10B 12/33

(57) ABSTRACT

A semiconductor storage device includes an oxide semiconductor that extends in a first direction, an insulating film on a side surface of the oxide semiconductor, a gate electrode that faces the insulating film, a first electrode that includes a first conductor which contains a first oxide conductive material and is connected to an upper end of the oxide semiconductor, a second electrode that extends in the first direction and includes a second conductor containing a second oxide conductive material and connected to a lower end of the oxide semiconductor, a dielectric layer on an outer peripheral surface of the second electrode, and a third electrode on an outer peripheral surface of the dielectric layer. The second conductor has a first surface that faces an inner peripheral surface of the third electrode with the dielectric layer interposed therebetween.

### CROSS-REFERENCE TO RELATED APPLICATION

This application is based upon and claims the benefit of priority from Japanese Patent Application No. 2024-158967, filed Sep. 13, 2024, the entire contents of which are incorporated herein by reference.

### FIELD

Embodiments described herein relate generally to a semiconductor storage device and a semiconductor device.

### BACKGROUND

In some semiconductor elements, a metal oxide containing indium and tin is used for an electrode.

### BRIEF DESCRIPTION OF THE DRAWINGS

FIG. 1 is a circuit diagram illustrating a memory cell array according to a first embodiment.

FIG. 2 is a schematic cross-sectional view illustrating a semiconductor storage device according to the first embodiment, and shows a cross-sectional view parallel to a ZX plane.

FIG. 3 shows a detailed cross-sectional view of the semiconductor storage device as seen in a cross section provided in an oxide semiconductor layer, the cross section parallel to the ZX plane.

FIG. 4 shows a detailed cross-sectional view of the semiconductor storage device as seen in a cross section provided in the oxide semiconductor layer, the cross section parallel to a YZ plane.

FIG. 5 is a cross-sectional view parallel to the YZ plane, showing a manufacturing process of the semiconductor storage device according to the first embodiment.

FIG. 6 is a cross-sectional view parallel to the YZ plane, showing the manufacturing process of the semiconductor storage device according to the first embodiment.

FIG. 7 is a cross-sectional view parallel to the YZ plane, showing the manufacturing process of the semiconductor storage device according to the first embodiment.

FIG. 8 is a cross-sectional view parallel to the YZ plane, showing the manufacturing process of the semiconductor storage device according to the first embodiment.

FIG. 9 is a cross-sectional view parallel to the YZ plane, showing the manufacturing process of the semiconductor storage device according to the first embodiment.

FIG. 10 is a cross-sectional view parallel to the YZ plane, showing the manufacturing process of the semiconductor storage device according to the first embodiment.

FIG. 11 is a cross-sectional view parallel to the YZ plane, showing the manufacturing process of the semiconductor storage device according to the first embodiment.

FIG. 12 is a cross-sectional view parallel to the YZ plane, showing the manufacturing process of the semiconductor storage device according to the first embodiment.

FIG. 13 is a cross-sectional view parallel to the YZ plane, showing the manufacturing process of the semiconductor storage device according to the first embodiment.

FIG. 14 is a cross-sectional view parallel to the YZ plane, showing the manufacturing process of the semiconductor storage device according to the first embodiment.

FIG. 15 is a cross-sectional view parallel to the YZ plane, showing the manufacturing process of the semiconductor storage device according to the first embodiment.

FIG. 16 is a cross-sectional view parallel to the YZ plane, showing the manufacturing process of the semiconductor storage device according to the first embodiment.

FIG. 17 is a cross-sectional view parallel to the YZ plane, showing the manufacturing process of the semiconductor storage device according to the first embodiment.

FIG. 18 is a cross-sectional view parallel to the YZ plane, showing the manufacturing process of the semiconductor storage device according to the first embodiment.

FIG. 19 is a cross-sectional view parallel to the YZ plane, showing the manufacturing process of the semiconductor storage device according to the first embodiment.

FIG. 20 is a cross-sectional view parallel to the YZ plane, showing the manufacturing process of the semiconductor storage device according to the first embodiment.

FIG. 21 is a cross-sectional view parallel to the YZ plane, showing the manufacturing process of the semiconductor storage device according to the first embodiment.

FIG. 22 is a cross-sectional view parallel to the YZ plane, showing the manufacturing process of the semiconductor storage device according to the first embodiment.

FIG. 23 is a cross-sectional view parallel to the YZ plane, showing the manufacturing process of the semiconductor storage device according to the first embodiment.

FIG. 24 is a cross-sectional view parallel to the YZ plane, showing the manufacturing process of the semiconductor storage device according to the first embodiment.

FIG. 25 is a cross-sectional view parallel to the YZ plane, showing a manufacturing process of a capacitor.

FIG. 26 is a cross-sectional view parallel to the YZ plane, showing the manufacturing process of the capacitor.

FIG. 27 is a cross-sectional view parallel to the YZ plane, showing the manufacturing process of the capacitor.

FIG. 28 is a cross-sectional view parallel to the YZ plane, showing the manufacturing process of the capacitor.

FIG. 29 is a cross-sectional view parallel to the YZ plane, showing the manufacturing process of the capacitor.

FIG. 30 shows a detailed cross-sectional view of a modification example of the semiconductor storage device as seen in the cross section provided in the oxide semiconductor layer, the cross section parallel to the ZX plane.

FIG. 31 shows a detailed cross-sectional view of the modification example of the semiconductor storage device as seen in the cross section provided in the oxide semiconductor layer, the cross section parallel to the YZ plane.

FIG. 32 shows a cross-sectional view of a semiconductor storage device as seen in the cross section provided in the oxide semiconductor layer, the cross section parallel to the ZX plane.

FIG. 33 is a plan view of a capacitor as viewed from an upper side thereof.

FIG. 34 is a schematic view illustrating a seam.

FIG. 35 is a plan view of a metal oxide layer as viewed from a lower side thereof.

FIG. 36 is a cross-sectional view parallel to the ZX plane, showing a manufacturing process of a semiconductor device according to a comparative example.

FIG. 37 is a cross-sectional view parallel to the ZX plane, showing the manufacturing process of the semiconductor device according to the comparative example.

FIG. 38 is a cross-sectional view parallel to the ZX plane, showing the manufacturing process of the semiconductor device according to the comparative example.

FIG. 39 is a cross-sectional view parallel to the ZX plane, showing the manufacturing process of the semiconductor device according to the comparative example.

FIG. 40 is a cross-sectional view parallel to the ZX plane, showing the manufacturing process of the semiconductor device according to the comparative example.

FIG. 41 is a cross-sectional view parallel to the ZX plane, showing a manufacturing process of a semiconductor storage device according to a second embodiment.

FIG. 42 is a cross-sectional view parallel to the ZX plane, showing the manufacturing process of the semiconductor storage device according to the second embodiment.

FIG. 43 is a cross-sectional view parallel to the ZX plane, showing the manufacturing process of the semiconductor storage device according to the second embodiment.

FIG. 44 is a cross-sectional view parallel to the ZX plane, showing the manufacturing process of the semiconductor storage device according to the second embodiment.

FIG. 45 is a cross-sectional view parallel to the ZX plane, showing the manufacturing process of the semiconductor storage device according to the second embodiment.

FIG. 46 is a view illustrating a seam, which is a modification example of the seam.

FIG. 47 is a view illustrating a seam, which is a modification example of the seam.

FIG. 48 is a view illustrating a seam, which is a modification example of the seam.

FIG. 49 is a view illustrating a seam, which is a modification example of the seam.

### DETAILED DESCRIPTION

Embodiments provide a high-quality semiconductor device and a semiconductor storage device with an electrode containing a metal oxide.

In general, according to one embodiment, a semiconductor storage device includes an oxide semiconductor that extends in a first direction, an insulating film on a side surface of the oxide semiconductor, a gate electrode that faces the insulating film, a first electrode that includes a first conductor which contains a first oxide conductive material and is connected to an upper end of the oxide semiconductor, a second electrode that extends in the first direction and includes a second conductor containing a second oxide conductive material and connected to a lower end of the oxide semiconductor, a dielectric layer on an outer peripheral surface of the second electrode, and a third electrode on an outer peripheral surface of the dielectric layer. The second conductor has a first surface that faces an inner peripheral surface of the third electrode with the dielectric layer interposed therebetween.

Hereinafter, embodiments of this disclosure will be described with reference to the drawings. In order to facilitate understanding of the description, the same elements are designated by the same reference numerals as much as possible in each drawing, and duplicate description is omitted.

### First Embodiment

A structure of a semiconductor storage device 101 according to a first embodiment will be described. Each drawing may show an X-axis, a Y-axis, and a Z-axis. The X-axis, the Y-axis, and the Z-axis form a three-dimensional right-handed orthogonal coordinate. Hereinafter, the arrow direction of the X-axis may be referred to as an X-axis +direction, and the opposite direction to the arrow may be referred to as an X-axis+direction, and the same applies to other axes. A Z-axis+direction and a Z-axis−direction may also be referred to as an “upper side” and a “lower side”, respectively. In addition, a plane orthogonal to each of the X-axis, the Y-axis, or the Z-axis may be referred to as a YZ plane, a ZX plane, or an XY plane. In addition, a Z-axis direction may be referred to as an “up-down direction”. The terms “upper side”, “lower side”, and “up-down direction” are terms indicating a relative positional relationship in the drawing, and are not terms for determining an orientation based on a vertical direction.

In the present specification, the term “connection” includes not only a physical connection but also an electrical connection, and includes not only a direct connection but also an indirect connection, unless otherwise specified.

In the present specification, the term “formed on the upper side” includes not only when the thing is formed in contact with the upper side but also when the thing is formed on the upper side another thing interposed therebetween, unless otherwise specified. The same also applies to a case of “formed on the lower side” or the like.

The semiconductor storage device 101 according to the first embodiment is an oxide semiconductor-random access memory (OS-RAM) and includes a memory cell array.

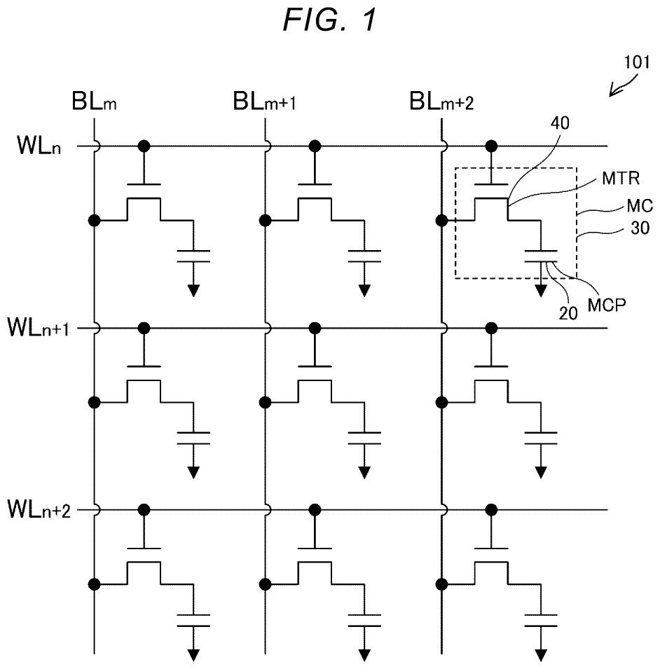

As shown in FIG. 1, the memory cell array includes a plurality of memory cells MC, a plurality of word lines WL, and a plurality of bit lines BL.

In FIG. 1, as examples of the plurality of word lines WL, a word line WLn, a word line WLn+1, and a word line WLn+2 are shown (here, n is a positive integer). In addition, in FIG. 1, as examples of a bit line BL, a bit line BLm, a bit line BLm+1, and a bit line BLm+2 are shown (here, m is a positive integer). The number of the plurality of memory cells MC is not limited to the number shown in FIG. 1.

The plurality of memory cells MC are arranged in a matrix shape, for example, to form a memory cell array. The memory cell MC includes a memory transistor MTR which is a field effect transistor (FET) and a memory capacitor MCP.

A series of memory cells MC provided in a row direction are connected to the word line WL (for example, the word line WLn) corresponding to a row (for example, the n-th row) to which the memory cells MC belong. A series of memory cells MC provided in a column direction are connected to the bit line BL (for example, the bit line BLm+2) corresponding to a column (for example, the m+2-th column) to which the memory cells MC belong.

Specifically, the gate of the memory transistor MTR provided in the memory cell MC is connected to the word line WL corresponding to the row to which the memory cell MC belongs. One of the source or the drain of the memory transistor MTR is connected to the bit line BL corresponding to the column to which the memory cell MC belongs.

One electrode of the memory capacitor MCP provided in the memory cell MC is connected to the other of the source or the drain of the memory transistor MTR provided in the memory cell MC. The other electrode of the memory cell MC is connected to a power supply line (not shown) that applies a specific voltage.

The memory cell MC stores data by accumulating charges in the memory capacitor MCP with a current flowing in the corresponding bit line BL by switching of the memory transistor MTR based on the voltage of the corresponding word line WL.

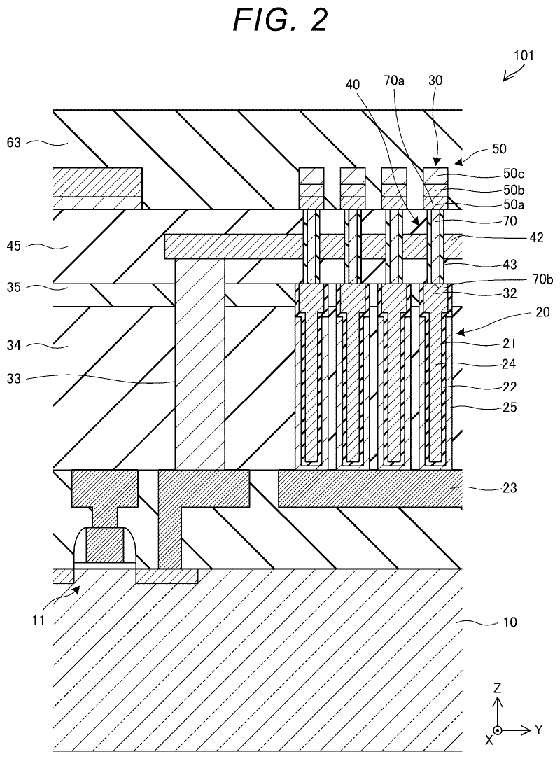

As shown in FIG. 2, the semiconductor storage device 101 includes a semiconductor substrate 10, a circuit 11 (e.g., a semiconductor circuit), a capacitor 20, a semiconductor device 30, a conductor 33, and insulating layers 34, 35, and 63.

The capacitor 20 includes a dielectric layer 22 (e.g., a dielectric film), a conductor 23, an electrode 24, and an electrode 25.

The semiconductor device 30 includes a field effect transistor 40 (hereinafter also referred to as “a semiconductor element”), an electrode 50 provided on the upper side of the field effect transistor 40, and an electrode 24 provided on the lower side of the field effect transistor 40.

The field effect transistor 40 includes an oxide semiconductor layer 70, a gate insulating film 43, a conductive layer 42 (e.g., a gate electrode), and an insulating layer 45. The field effect transistor 40 corresponds to the memory transistor MTR of the memory cell MC (refer to FIG. 1).

The oxide semiconductor layer 70 is formed in the insulating layer 45 and has an upper end 70a and a lower end 70b. The oxide semiconductor layer 70 is a columnar shape body extending in the up-down direction. The oxide semiconductor layer 70 has a center axis 70d that is substantially parallel to a Z-axis. The oxide semiconductor layer 70 forms a channel of the field effect transistor 40. The oxide semiconductor layer 70 has an amorphous structure.

The oxide semiconductor layer 70 is a semiconductor in which oxygen deficiency acts as a donor. The oxide semiconductor layer 70 contains at least one of indium (In), gallium (Ga), zinc (Zn), tin (Sn), aluminum (Al), iridium (Ir), ruthenium (Ru), or titanium (Ti), and oxygen.

In the present embodiment, the oxide semiconductor layer 70 contains indium, zinc, and gallium as metal elements. Specifically, the oxide semiconductor layer 70 is an oxide of indium, gallium, and zinc, that is, IGZO (InGaZnO). The oxide semiconductor layer 70 may be another type of oxide semiconductor.

The field effect transistor 40 is a so-called vertical transistor having a channel extending in the Z-axis direction (i.e., the up-down direction) substantially perpendicular to the surface of the semiconductor substrate 10.

The conductive layer 42 faces the oxide semiconductor layer 70 with the gate insulating film 43 interposed therebetween. Specifically, the conductive layer 42 functions as a gate electrode of the field effect transistor 40 and surrounds the oxide semiconductor layer 70 with the gate insulating film 43 interposed therebetween between the upper end 70a and the lower end 70b of the oxide semiconductor layer 70. The conductive layer 42 contains, for example, tungsten (W).

The conductive layer 42 is a plurality of electrodes extending substantially parallel to the Y-axis and repeatedly provided in the X-axis direction. The electrode corresponds to the word line WL (see FIG. 1).

The gate insulating film 43 contains, for example, a silicon nitride film (Si3N4) containing silicon and nitrogen. The gate insulating film 43 covers the side surface of the oxide semiconductor layer 70 over the entire circumference.

The electrode 50 is formed on the upper side of the oxide semiconductor layer 70 and is connected to the upper end 70a of the oxide semiconductor layer 70. The electrode 50 includes a metal oxide layer 50a, a barrier metal layer 50b, and a metal film 50c.

The metal oxide layer 50a is connected to the upper end 70a of the oxide semiconductor layer 70. In the present embodiment, the metal oxide layer 50a is in contact with the upper end 70a of the oxide semiconductor layer 70. The metal oxide layer 50a contains a first oxide conductive material. Specifically, the first oxide conductive material is an oxide conductive material containing indium and tin as metal elements. More specifically, the first oxide conductive material is an indium-tin-oxide (ITO).

The metal film 50c is provided on the upper side of the metal oxide layer 50a and contains tungsten. The barrier metal layer 50b is formed between the metal oxide layer 50a and the metal film 50c. The barrier metal layer 50b contains, for example, titanium and nitrogen. In the present embodiment, the barrier metal layer 50b is formed of titanium nitride (TiN).

The circuit 11 is a peripheral circuit such as a decoder for selecting a predetermined memory cell MC, a sense amplifier connected to the bit line BL, and a register configured with an SRAM, among the plurality of memory cells MC of the semiconductor storage device 101, that is, the capacitor 20 and the field effect transistor 40. The circuit 11 may include a CMOS circuit having a field effect transistor of a P-channel type field effect transistor (Pch-FET) and an N-channel type field effect transistor (Nch-FET), which are formed by a CMOS process.

The field effect transistor of the circuit 11 may be formed using, for example, the semiconductor substrate 10 such as a single crystal silicon substrate. The Pch-FET and the Nch-FET are so-called horizontal field effect transistors having a channel region, a source region, and a drain region in the semiconductor substrate 10, and having a channel for causing a carrier to flow in the X-axis direction or the Y-axis direction substantially parallel to the surface of the semiconductor substrate 10 in a region close to the surface of the semiconductor substrate 10. The semiconductor substrate 10 may have a conductive type of P-type or N-type. For convenience, FIG. 2 shows an example of the field effect transistor of the circuit 11.

The capacitor 20 is the memory capacitor MCP provided in the memory cell MC (refer to FIG. 1). Although the four capacitors 20 are shown in FIG. 2, the number of the capacitors 20 is not limited to four.

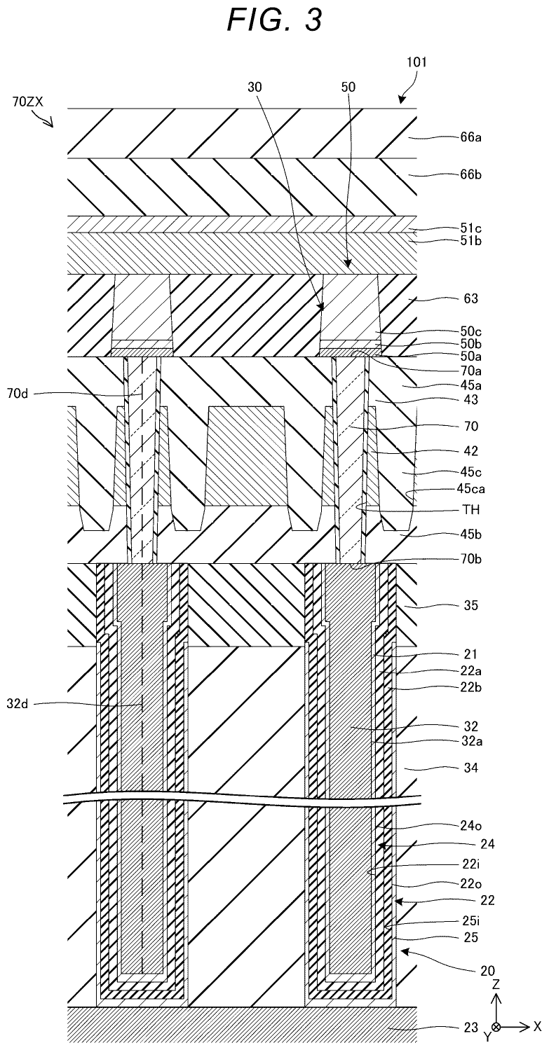

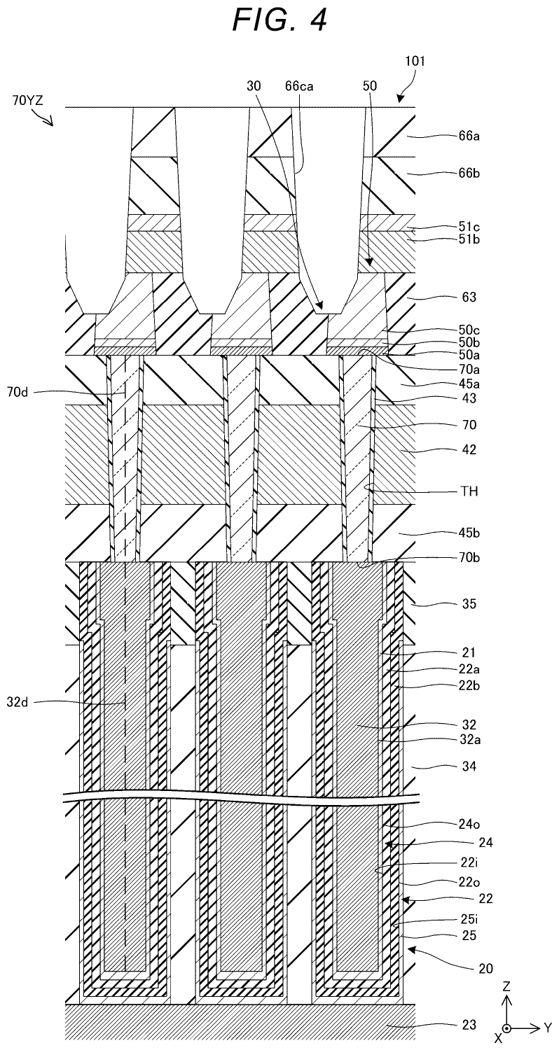

FIG. 3 shows a detailed cross-sectional view of the semiconductor storage device 101 as seen in a cross section 70ZX provided in an oxide semiconductor layer 70, the cross section 70ZX parallel to the ZX plane. FIG. 4 shows a detailed cross-sectional view of the semiconductor storage device 101 as seen in a cross section 70YZ provided in the oxide semiconductor layer 70, the cross section 70YZ parallel to the YZ plane.

As shown in FIGS. 3 and 4, the capacitor 20 is provided on the lower side of the oxide semiconductor layer 70 and the upper side of the semiconductor substrate 10. The electrode 24 in the capacitor 20 is provided on the lower side of the oxide semiconductor layer 70 and has a columnar shape extending in the up-down direction. The upper end portion of the electrode 24 is connected to the lower end 70b of the oxide semiconductor layer 70.

The dielectric layer 22 is provided on an outer peripheral surface 24o of the electrode 24. The electrode 25 is provided on an outer peripheral surface 22o of the dielectric layer 22.

Specifically, the electrode 24 includes a conductive film 21 and a metal oxide layer 32.

The metal oxide layer 32 contains a second oxide conductive material. The second oxide conductive material contains at least one of indium (In), zinc (Zn), tin (Sn), iridium (Ir), ruthenium (Ru), titanium (Ti), or tungsten (W), and oxygen.

In the present embodiment, the second oxide conductive material contains indium, tin, and oxygen. Specifically, the second oxide conductive material is indium-tin-oxide (ITO) similar to the metal oxide layer 50a.

The upper end portion of the metal oxide layer 32 is in contact with the lower end 70b of the oxide semiconductor layer 70. The metal oxide layer 32 has a columnar shape extending in the up-down direction. The metal oxide layer 32 has a center axis 32d that is substantially parallel to the Z-axis. The center axis 32d is aligned with the center axis 70d.

A portion on the lower side in the outer peripheral surface of the metal oxide layer 32 is a facing surface 32a facing an inner peripheral surface 25i of the electrode 25 with the dielectric layer 22 interposed therebetween.

The conductive film 21 on the electrode 24 is provided between the metal oxide layer 32 and the dielectric layer 22. Specifically, the conductive film 21 is provided on the outer peripheral surface of the metal oxide layer 32. The conductive film 21 has a cup shape in which the upper side thereof is open, and accommodates the metal oxide layer 32 in the cup.

The conductive film 21 contains, for example, titanium and nitrogen. In the present embodiment, the conductive film 21 is formed of titanium nitride. The outer peripheral surface of the conductive film 21 is the outer peripheral surface 24o of the electrode 24.

The dielectric layer 22 includes insulating films 22a and 22b. The insulating film 22a is provided on the outer peripheral surface 24o of the electrode 24. The insulating film 22a has a cup shape in which the upper side thereof is open, and accommodates the electrode 24 in the cup.

The insulating film 22b is provided on the outer peripheral surface of the insulating film 22a. The insulating film 22b has a cup shape in which the upper side thereof is open, and accommodates the insulating film 22a in the cup.

The upper end of the metal oxide layer 32, an upper opening end of the conductive film 21, an upper opening end of the insulating film 22a, and an upper opening end of the insulating film 22b are aligned in the Z direction.

The insulating films 22a and 22b are formed of a material having a high dielectric constant. Specifically, the insulating film 22a may contain a material such as ZrO containing zirconium and oxygen. The insulating film 22b may contain a material such as ZrAlO containing zirconium, aluminum, and oxygen. The outer peripheral surface of the insulating film 22b is the outer peripheral surface 22o of the dielectric layer 22.

The electrode 25 is provided on a portion on the lower side of the outer peripheral surface 22o of the dielectric layer 22. The electrode 25 has a cup shape in which the upper side thereof is open, and accommodates a portion on the lower side of the dielectric layer 22 in the cup. In addition, the electrode 25 has a lower end in contact with the upper surface of the conductor 23.

The electrode 25 contains, for example, titanium and nitrogen. In the present embodiment, the electrode 25 is formed of titanium nitride. The upper opening end of the electrode 25 is positioned further on the lower side than the upper end of the metal oxide layer 32. The inner peripheral surface 25i of the electrode 25 faces a portion on the lower side of the outer peripheral surface 24o of the electrode 24 with the dielectric layer 22 interposed therebetween.

The conductor 23 is in contact with the lower ends of a plurality of electrodes 25 provided in each of a plurality of capacitors 20. The conductor 23 functions as, for example, a ground electrode that is grounded. The conductor 23 may contain a material such as tungsten or titanium nitride.

As shown in FIG. 2, the conductor 33 includes a wiring that electrically connects the circuit 11 and the semiconductor device 30. The conductor 33 may include a via wiring, and for example, has a via wiring that extends in the Z-axis direction and connects the word line WL and the circuit 11 provided on the semiconductor substrate 10. The conductor 33 contains, for example, copper.

The insulating layer 34 is provided between the plurality of capacitors 20. The insulating layer 34 is, for example, a silicon oxide film containing silicon and oxygen.

The insulating layer 35 is provided on the upper side of the insulating layer 34. The insulating layer 35 is, for example, a silicon nitride film containing silicon and nitrogen. The upper surface of the insulating layer 35 is aligned in the Z direction with the upper end of the electrodes 24 and the upper end of the dielectric layer 22.

### Method of Manufacturing Semiconductor Storage Device

Hereinafter, a method of manufacturing the semiconductor storage device 101 according to the first embodiment will be described.

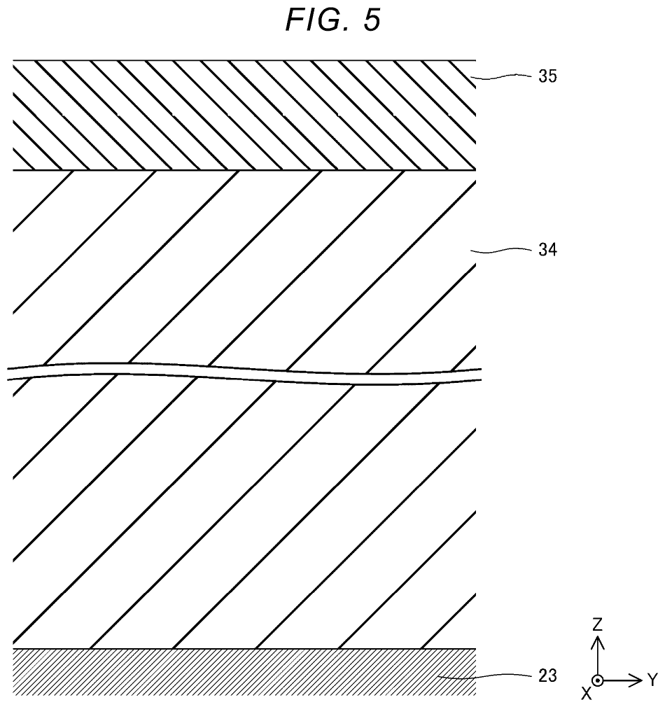

First, as shown in FIG. 5, the insulating layer 34 and the insulating layer 35 are formed in this order on the upper side of the conductor 23. Each of the conductor 23, the insulating layer 34, and the insulating layer 35 extends along a plane substantially parallel to the XY plane.

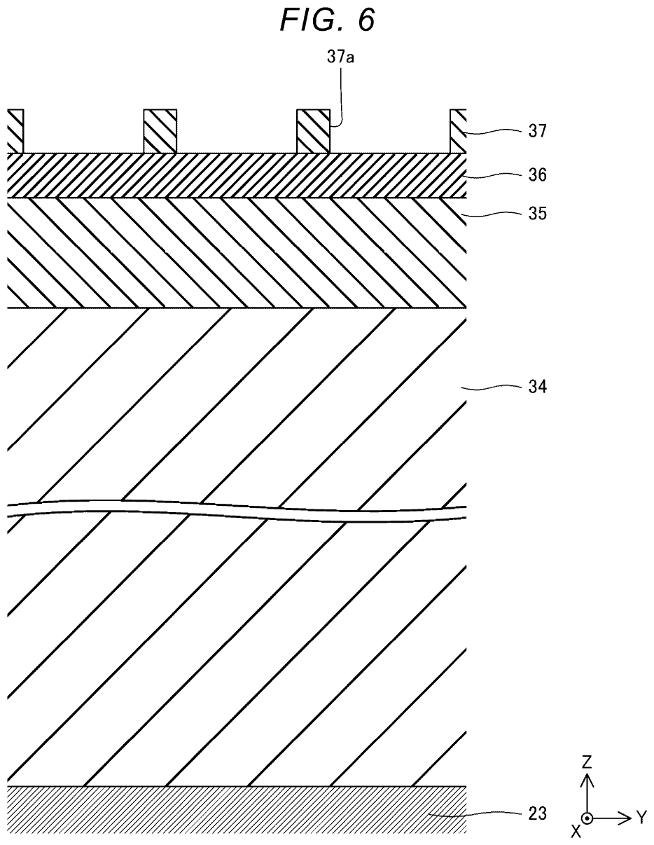

Next, as shown in FIG. 6, a hard mask layer 36 and a resist layer 37 are formed in this order on the upper side of the insulating layer 35. Each of the hard mask layer 36 and the resist layer 37 extends along a plane substantially parallel to the XY plane. Then, the surface of the resist layer 37 is exposed, developed, stripped, or the like by a lithography method, and a plurality of opening portions 37a are formed in the resist layer 37.

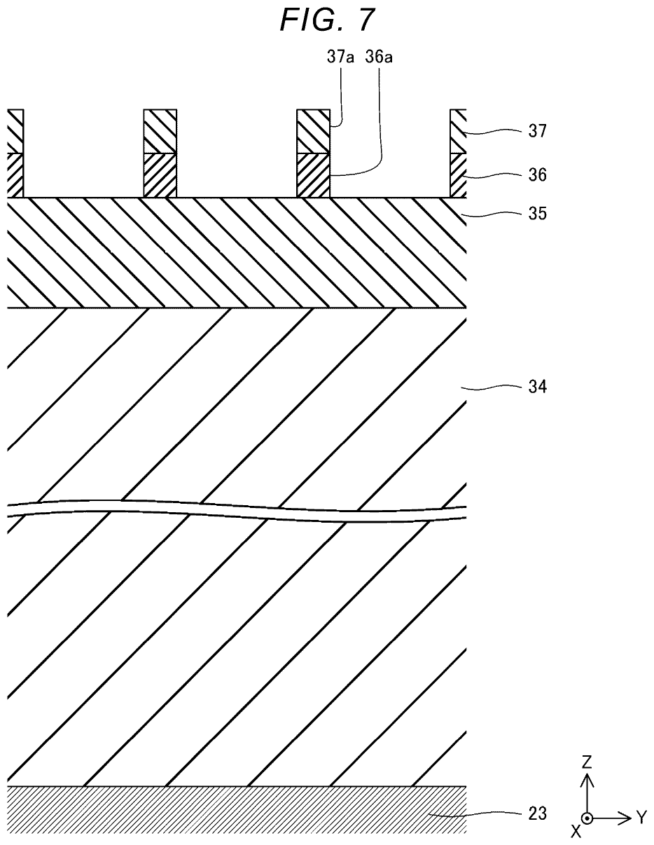

Next, as shown in FIG. 7, the hard mask layer 36 exposed through the opening portion 37a of the resist layer 37 is removed by reactive ion etching. As a result, the opening portion 36a continuous with the opening portion 37a is formed in the hard mask layer 36.

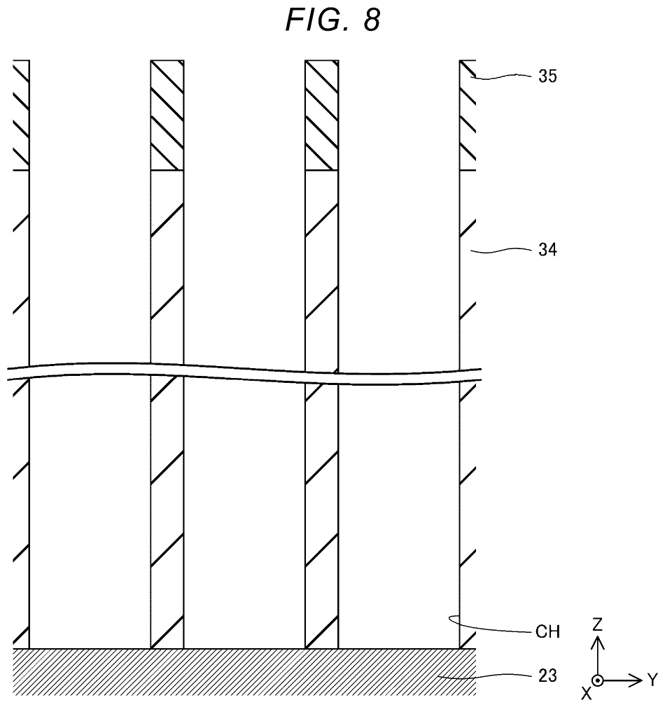

Next, as shown in FIG. 8, a portion of the insulating layer 35 and a portion of the insulating layer 34 are removed through the opening portions 37a and 36a by reactive ion etching. As a result, a capacitor hole CH is formed in which the bottom portion thereof reaches the conductor 23.

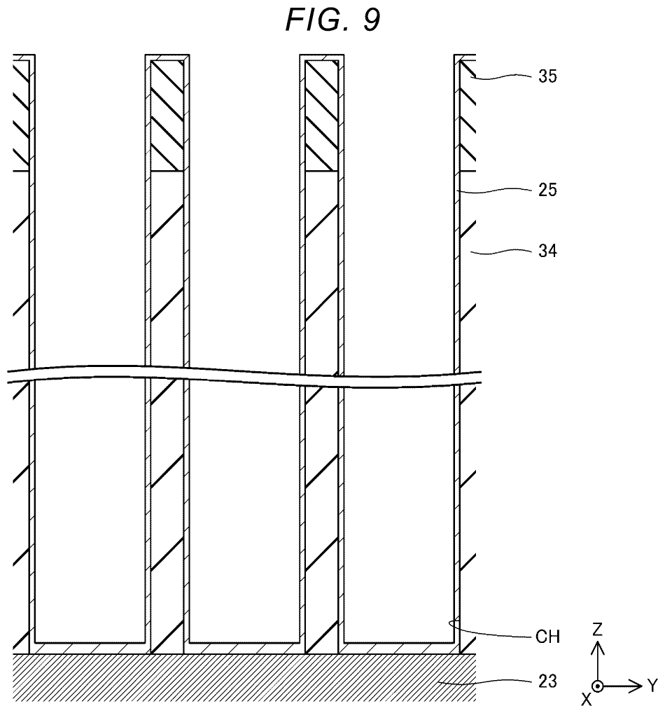

Next, as shown in FIG. 9, the electrode 25 is formed on the inner surface of the capacitor hole CH and the upper surface of the insulating layer 35.

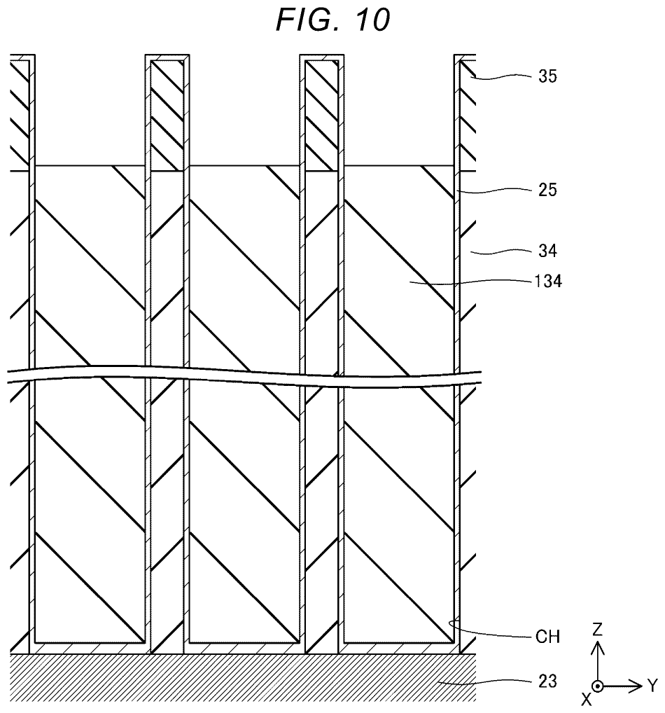

Next, as shown in FIG. 10, the insulating layer 134 is formed on the upper side of the electrode 25. The insulating layer 134 is, for example, a silicon oxide film containing silicon and oxygen. Then, a portion on the upper side of the insulating layer 134 is removed by reactive ion etching. As a result, the insulating layer 134 that fills a portion on the lower side of the capacitor hole CH is formed.

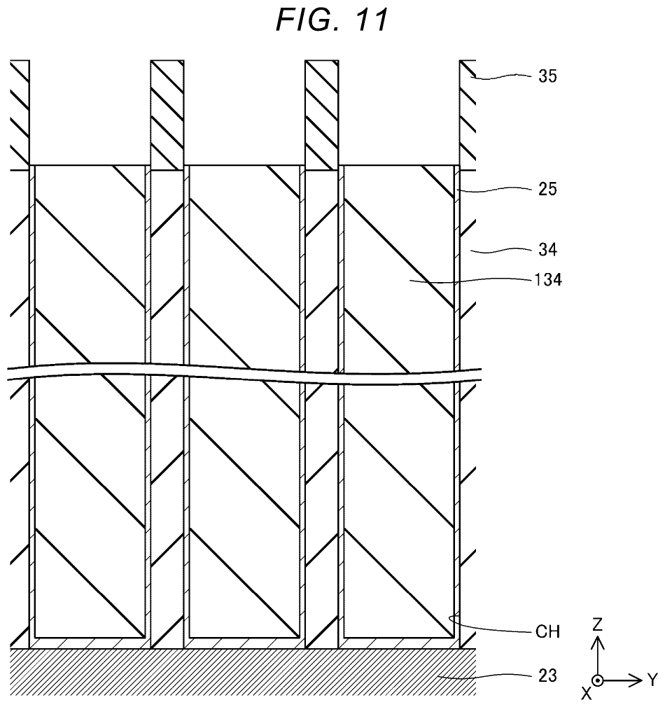

Next, as shown in FIG. 11, the electrode 25 exposed further on the upper side than the upper end portion of the insulating layer 134 is removed by etching. As a result, the electrode 25 provided on the inner surface of the capacitor hole CH is formed. The upper end portion of the electrode 25 is positioned further on the lower side than the upper surface of the insulating layer 35.

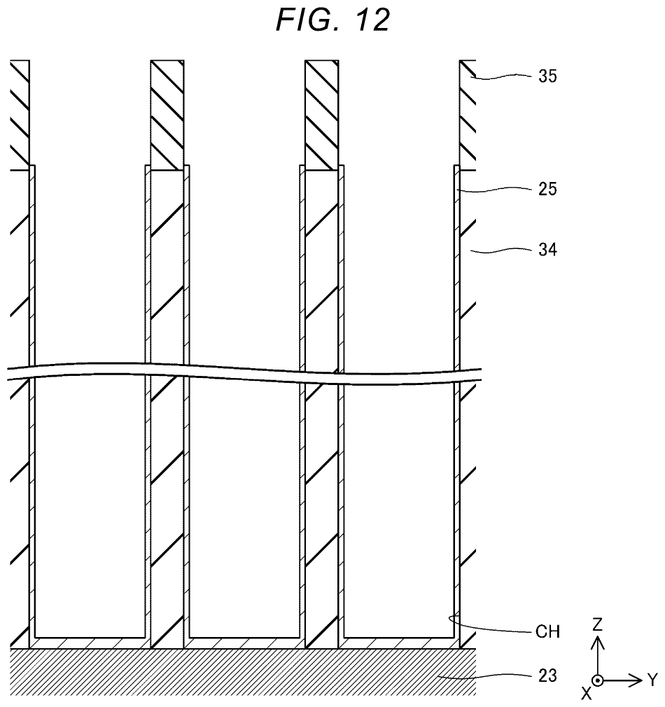

Next, as shown in FIG. 12, the insulating layer 134 inside the capacitor hole CH is removed by etching.

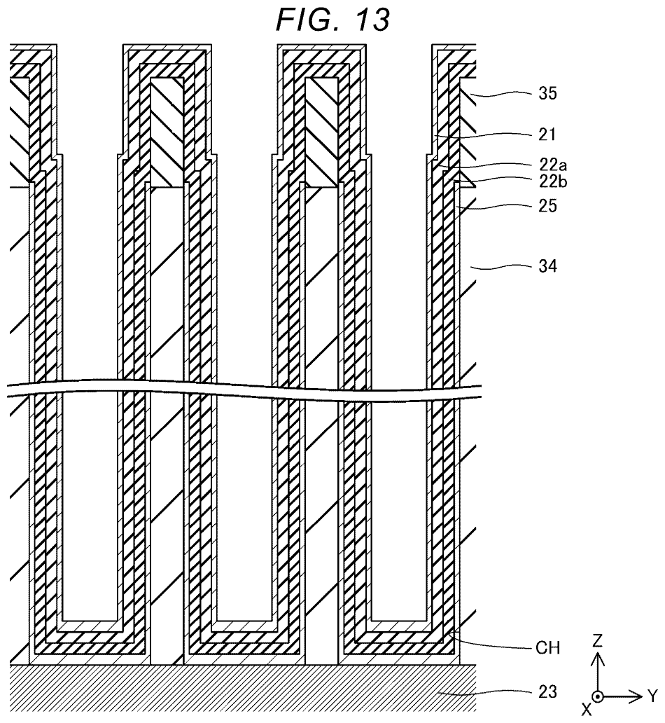

Next, as shown in FIG. 13, the insulating film 22b, the insulating film 22a, and the conductive film 21 are deposited in this order on the inner surface of the capacitor hole CH and the upper surface of the insulating layer 35.

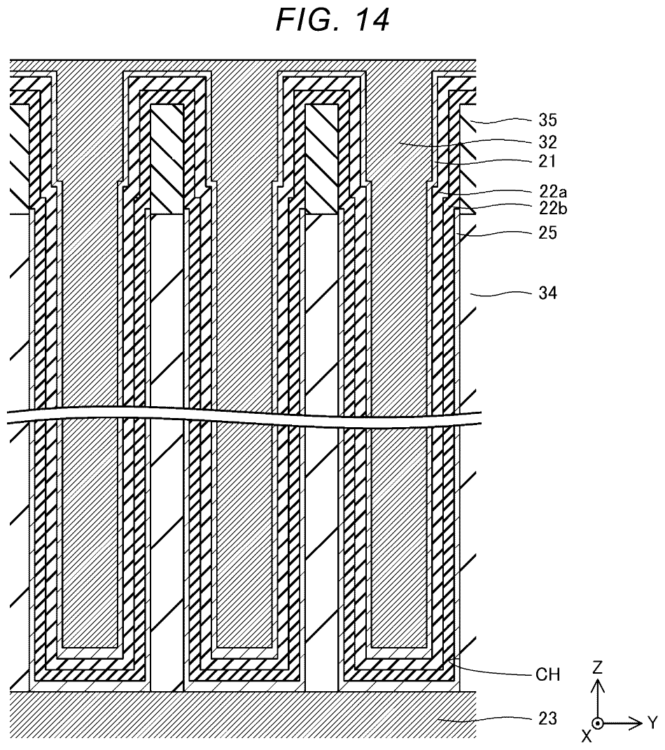

Next, as shown in FIG. 14, the metal oxide layer 32 is deposited on the upper surface of the conductive film 21. The metal oxide layer 32 is deposited inside the capacitor hole CH, for example, by atomic layer deposition (ALD).

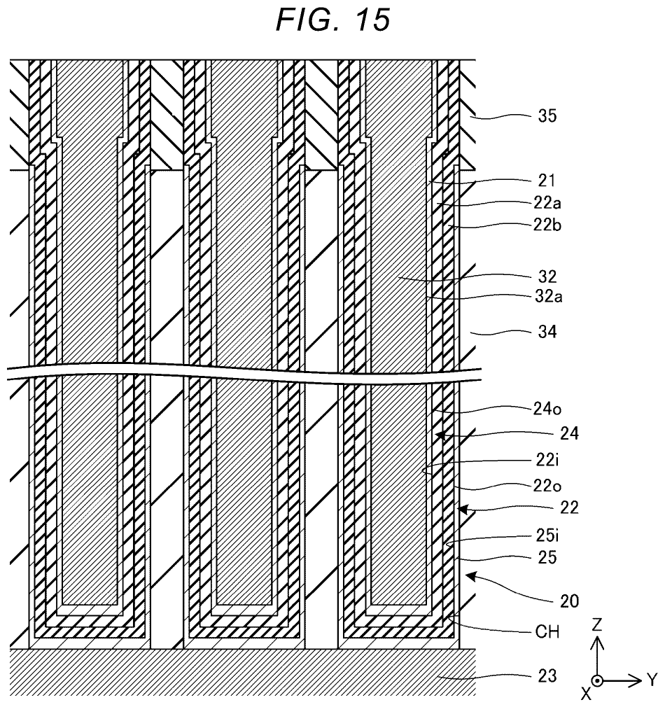

Next, as shown in FIG. 15, a portion on the upper side of each of the metal oxide layer 32, the conductive film 21, the insulating film 22a, and the insulating film 22b is removed by chemical mechanical polishing, and the insulating layer 35 is exposed. As a result, the metal oxide layer 32, the conductive film 21, the insulating film 22a, and the insulating film 22b separated for each of the capacitor holes CH are formed. The respective upper end portions of the metal oxide layer 32, the conductive film 21, the insulating film 22a, and the insulating film 22b are aligned in the Z direction.

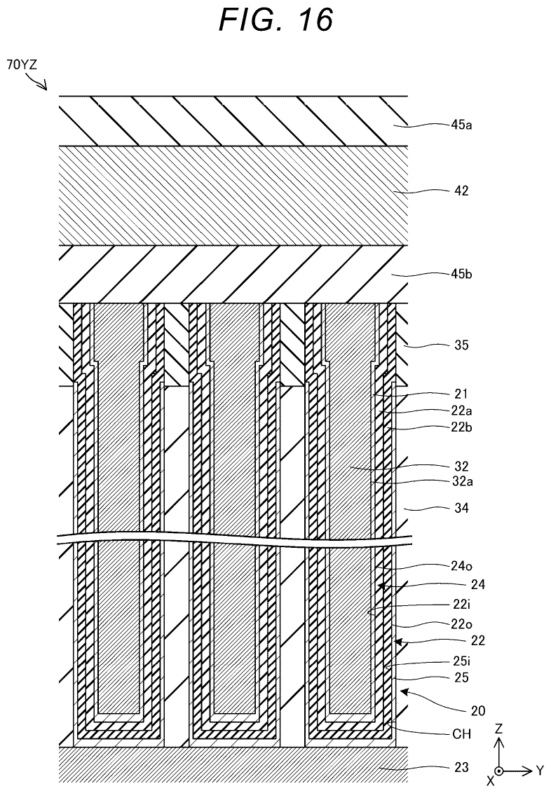

Next, as shown in FIG. 16, an insulating film 45b, the conductive layer 42, and an insulating film 45a are provided in this order on the upper side of the insulating layer 35. Each of the insulating film 45b, the conductive layer 42, and the insulating film 45a extends along a plane substantially parallel to the XY plane.

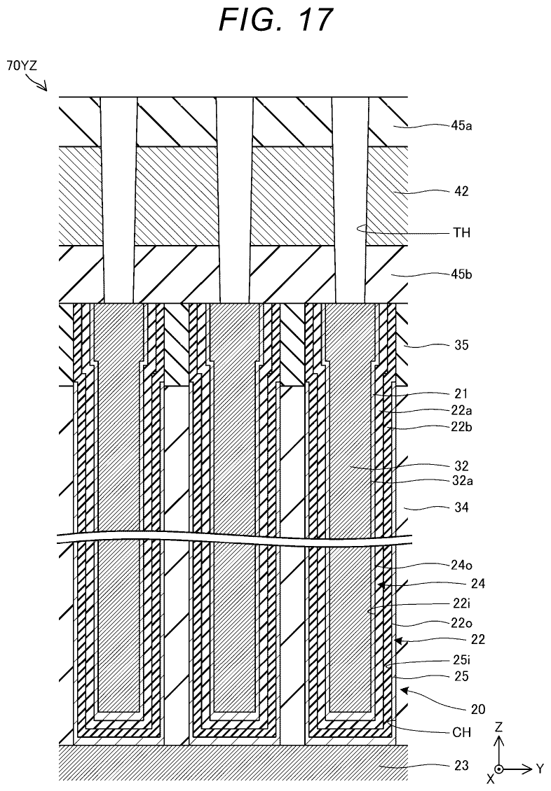

Next, as shown in FIG. 17, for example, a mask is formed on the upper side of the insulating film 45a by a lithography method, and then a transistor hole TH is formed by reactive ion etching. The transistor hole TH extends substantially parallel to the Z-axis and penetrates the insulating film 45a, the conductive layer 42, and the insulating film 45b. At the bottom portion of the transistor hole TH, an upper surface of the metal oxide layer 32 is exposed. The transistor hole TH has a tapered shape in which the cross section thereof goes into being smaller toward the lower side.

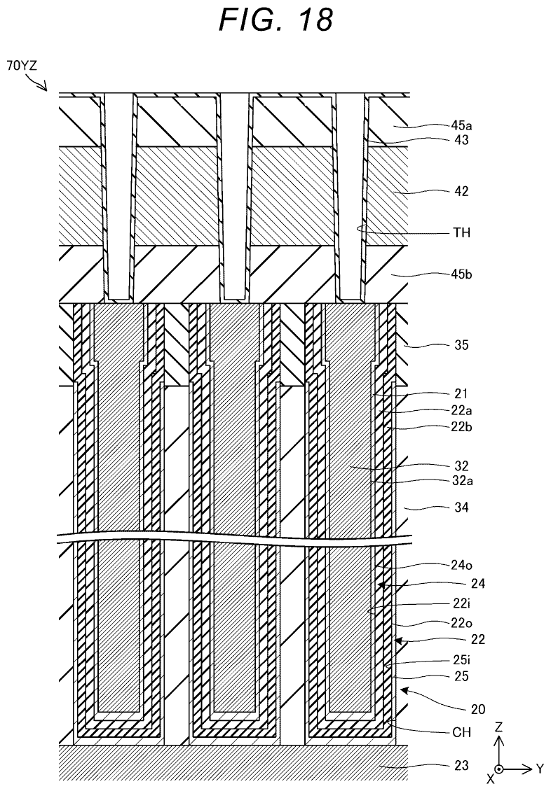

Next, as shown in FIG. 18, the gate insulating film 43 covers the upper surface of the insulating film 45a and the inner surface of the transistor hole TH.

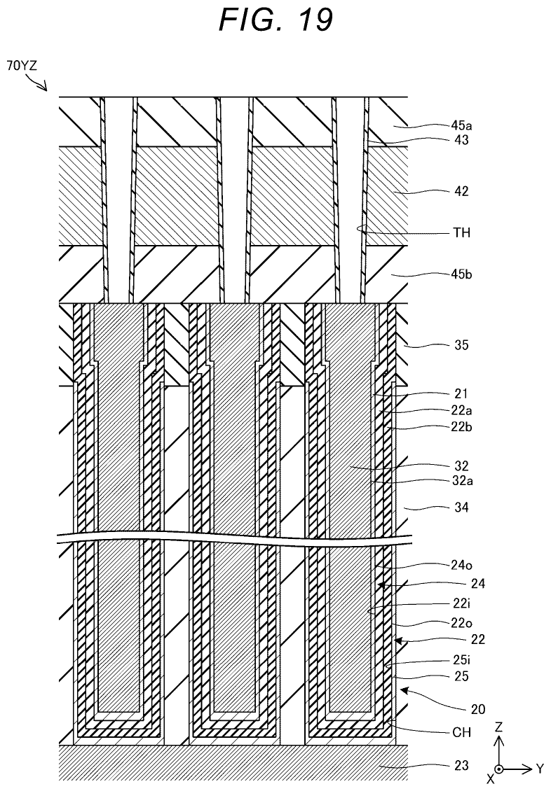

Next, as shown in FIG. 19, a portion of the gate insulating film 43 is etched by reactive ion etching. As a result, the upper surface of the metal oxide layer 32 is exposed at the bottom portion of the transistor hole TH.

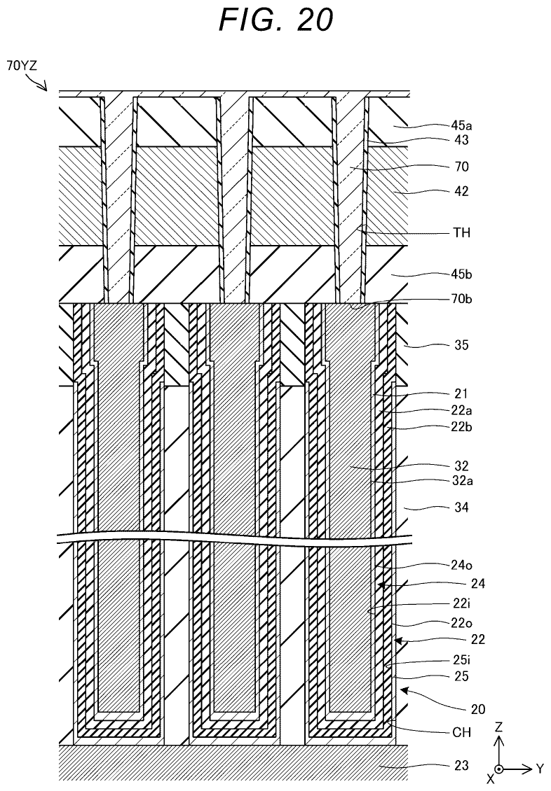

Next, as shown in FIG. 20, the oxide semiconductor layer 70 is formed on the upper surface of the insulating film 45a and the transistor hole TH. The lower end 70b of the oxide semiconductor layer 70 is in contact with the upper surface of the metal oxide layer 32 exposed at the bottom portion of the transistor hole TH. As a result, the transistor hole TH is filled with the oxide semiconductor layer 70.

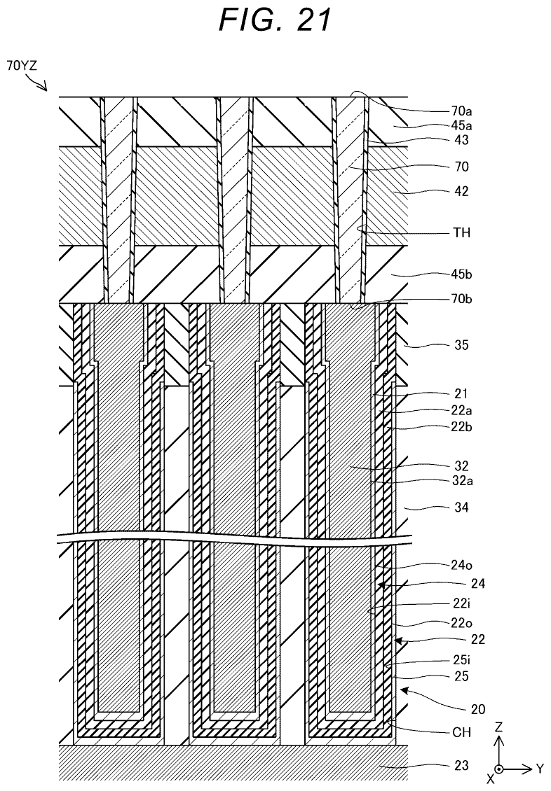

Next, as shown in FIG. 21, a portion of the oxide semiconductor layer 70 is removed, and the upper surface of the insulating film 45a is exposed. At this time, the surface of the upper end 70a of the oxide semiconductor layer 70 is aligned with the upper end portion of the gate insulating film 43 and the upper surface of the insulating film 45a in the Z direction.

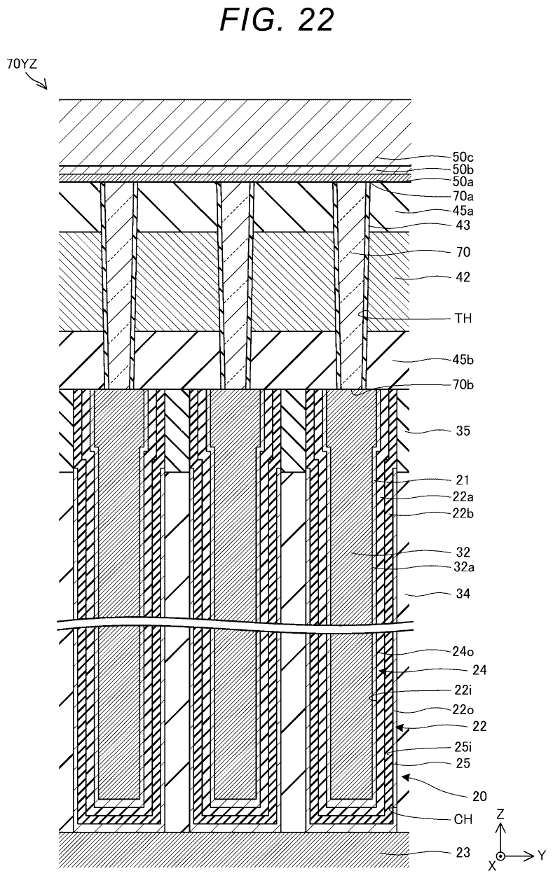

Next, as shown in FIG. 22, the metal oxide layer 50a, the barrier metal layer 50b, and the metal film 50c are formed in this order on the upper side of the oxide semiconductor layer 70 and the insulating film 45a. Each of the metal oxide layer 50a, the barrier metal layer 50b, and the metal film 50c extends along a plane substantially parallel to the XY plane.

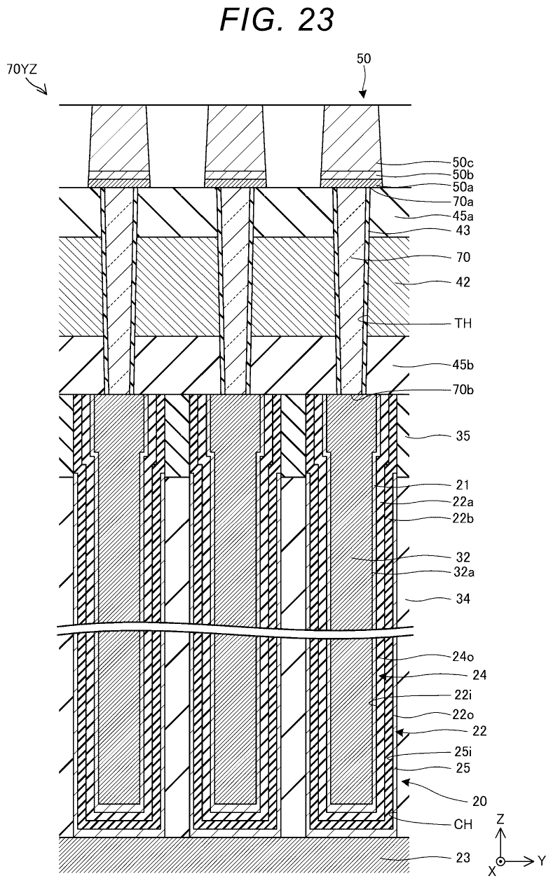

Next, as shown in FIG. 23, the electrode 50 is formed for each of the oxide semiconductor layers 70 by etching a portion of each of the metal film 50c, the barrier metal layer 50b, and the metal oxide layer 50a. The electrode 50 functions as a landing pad.

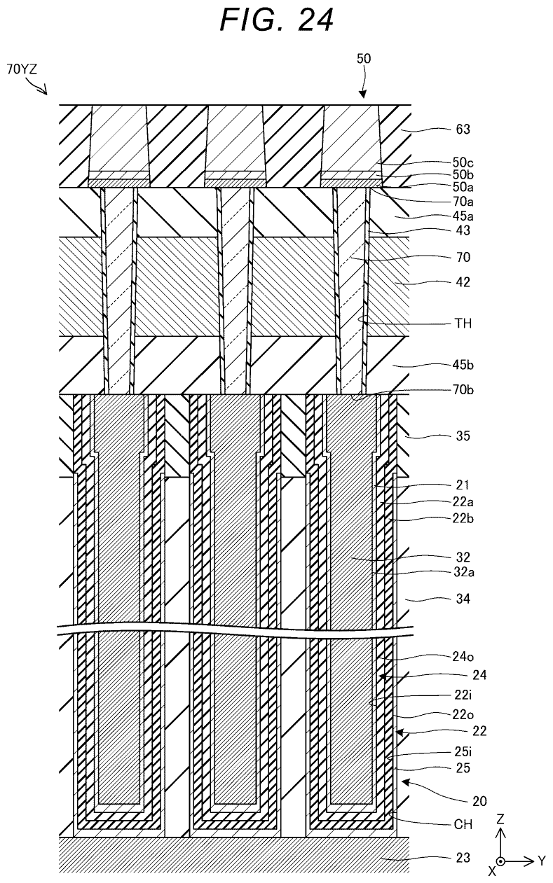

Next, as shown in FIG. 24, the insulating layer 63 covers the electrode 50. The insulating layer 63 contains, for example, a silicon oxide. Then, a portion of the insulating layer 63 is chemically mechanically polished, and the upper surface of the electrode 50 is exposed.

### Method of Manufacturing Capacitor 120

Hereinafter, a method of manufacturing a capacitor 120 having a structure different from the structure of the capacitor 20 will be described.

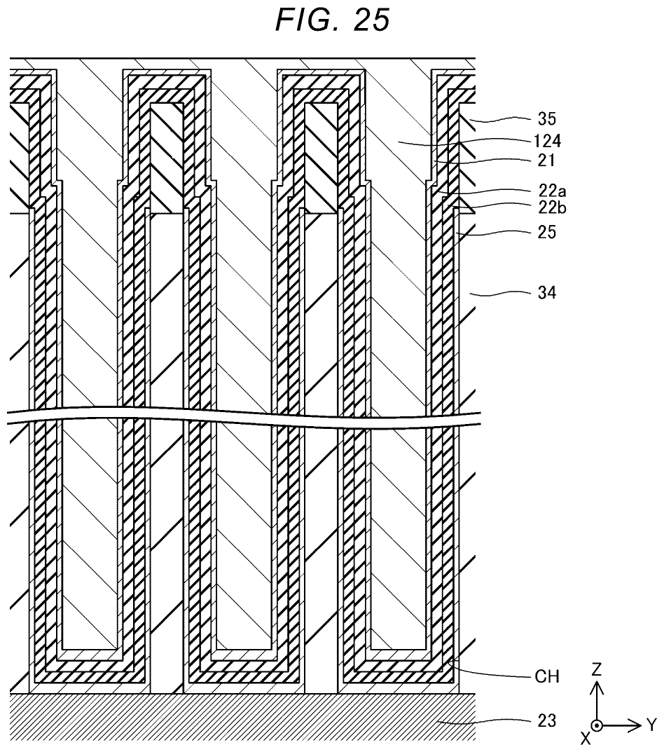

First, as shown in FIG. 25, when the method of manufacturing the capacitor 120 is compared to the method of manufacturing the capacitor 20 shown in FIG. 15, the electrode 124 instead of the metal oxide layer 32 is deposited on the upper surface of the conductive film 21. The electrode 124 contains, for example, SiGe containing silicon and germanium. The electrode 124 is deposited inside the capacitor hole CH, for example, by chemical vapor deposition (CVD).

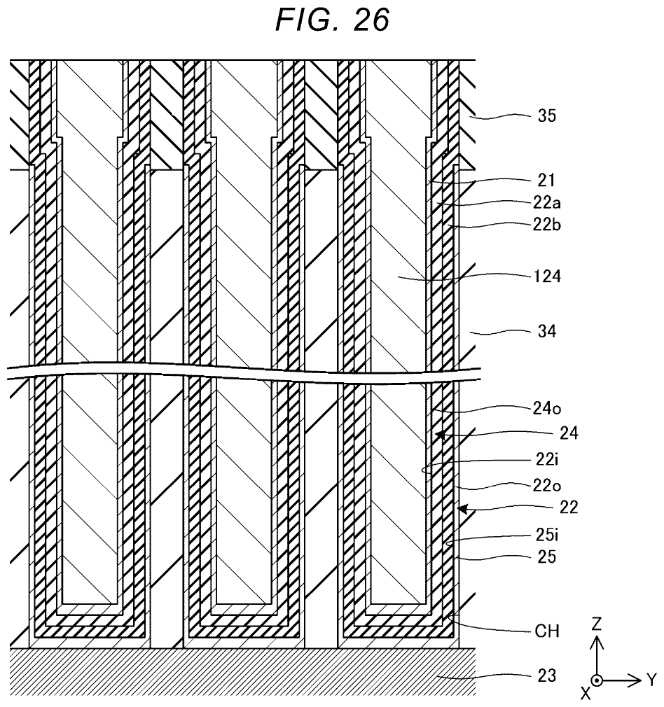

Next, as shown in FIG. 26, a portion on the upper side of each of the electrode 124, the conductive film 21, the insulating film 22a, and the insulating film 22b is removed by chemical mechanical polishing, and the insulating layer 35 is exposed. As a result, the electrode 124, the conductive film 21, the insulating film 22a, and the insulating film 22b separated for each of the capacitor holes CH are formed. The respective upper end portions of the electrode 124, the conductive film 21, the insulating film 22a, and the insulating film 22b are aligned in the Z direction.

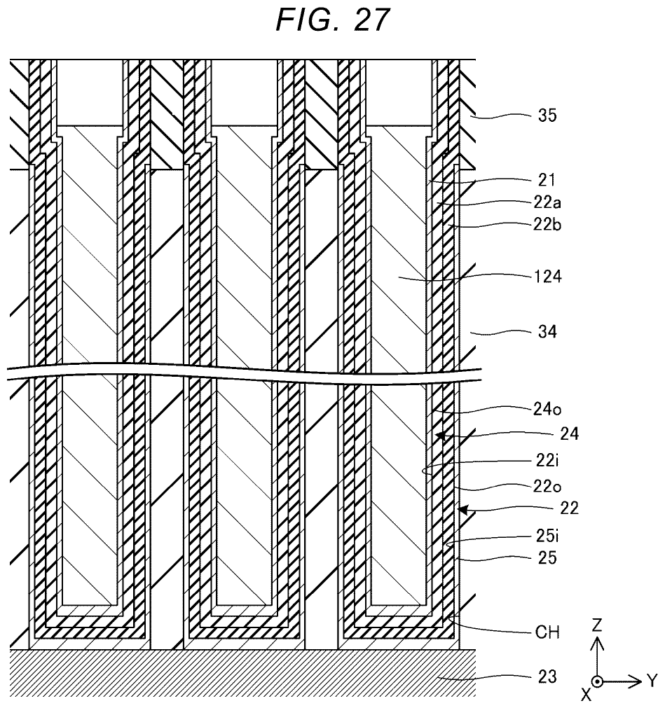

Next, as shown in FIG. 27, a portion on the upper side of the electrode 124 is removed by etching. As a result, the electrode 124 that fills a portion on the lower side of the capacitor hole CH is formed.

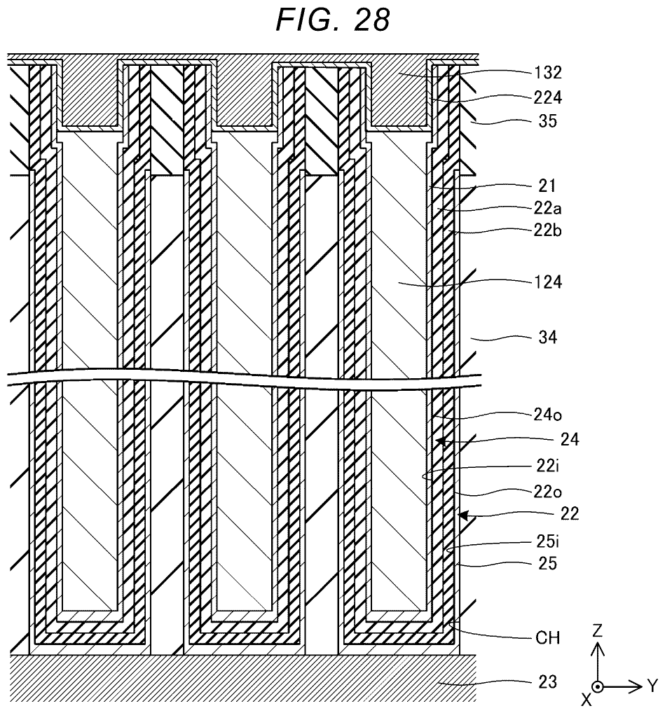

Next, as shown in FIG. 28, a barrier metal layer 224 and a metal oxide layer 132 are deposited in this order on the upper side of the capacitor hole CH. The barrier metal layer 224 contains, for example, titanium nitride containing nitrogen and titanium. The metal oxide layer 132 contains, for example, ITO.

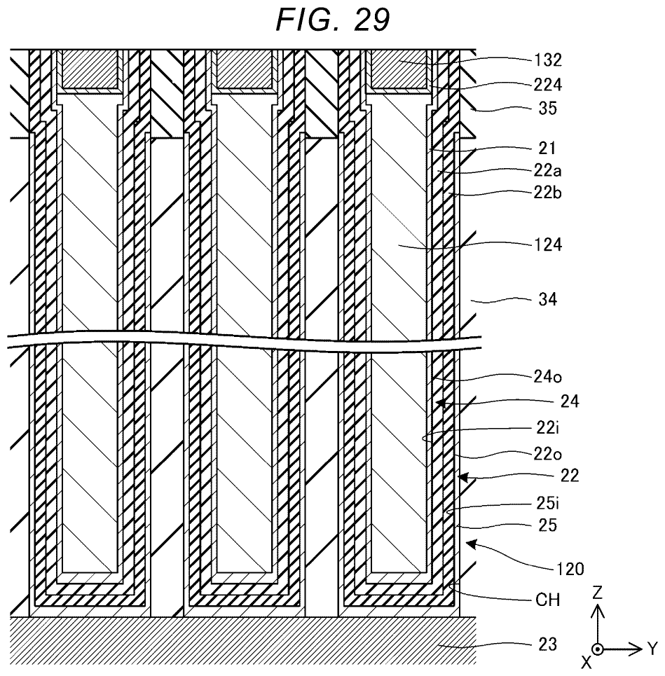

Next, as shown in FIG. 29, a portion on the upper side of each of the metal oxide layer 132 and the barrier metal layer 224 is removed by chemical mechanical polishing, and the insulating layer 35 is exposed. Then, the respective upper end portions of the insulating layer 35, the insulating film 22b, the insulating film 22a, the conductive film 21, the barrier metal layer 224, and the metal oxide layer 132 are aligned in the Z direction.

### Effect

As shown in FIGS. 25 to 29, the method of manufacturing the capacitor 120 includes the steps of chemical mechanical polishing, a recess formation by removing a portion on the upper side of the electrode 124, and the deposition of the barrier metal layer 224 and the metal oxide layer 132 and chemical mechanical polishing, from the deposition of the electrode 124 to the completion of the capacitor 120.

On the other hand, in the method of manufacturing the capacitor 20, as shown in FIGS. 14 and 15, the capacitor 20 is completed by depositing the metal oxide layer 32 and then performing chemical mechanical polishing. That is, the capacitor 20 can be manufactured by a simple step.

In addition, in the capacitor 120, the resistance value is increased due to the contact resistances between the metal oxide layer 132 and the barrier metal layer 224 and between the barrier metal layer 224 and the electrode 124.

On the other hand, in the capacitor 20, the resistance value can be reduced since the contact resistance does not occur by a structure in which the metal oxide layer 32 is provided instead of the metal oxide layer 132, the electrode 124, and the barrier metal layer 224.

In addition, the metal oxide layer 132 in the capacitor 120 has a smaller volume as compared with the metal oxide layer 32 in the capacitor 20. Consequently, the metal oxide layer 132 may disappear by the formation step (see FIG. 18) and the etching step (see FIG. 19) of the gate insulating film 43.

On the other hand, the capacitor 20 has a structure in which the volume of the metal oxide layer 32 is large, so that the disappearance of the metal oxide layer 132 in the formation step (see FIG. 18) and the etching step (see FIG. 19) of the gate insulating film 43 can be prevented.

Although a structure in which the electrode 124 (see FIG. 26) provided instead of the metal oxide layer 32 is brought into contact with the lower end 70b of the oxide semiconductor layer 70 is also conceivable, the work function matching of SiGe and IGZO is poor, so that the resistance value goes into being high.

On the other hand, in the semiconductor storage device 101, the resistance value can be reduced by a structure in which the metal oxide layer 32 (ITO) and the lower end 70b of the oxide semiconductor layer 70 (IGZO) having good work function matching are brought into contact with each other.

### Modification Example of Semiconductor Storage Device 101

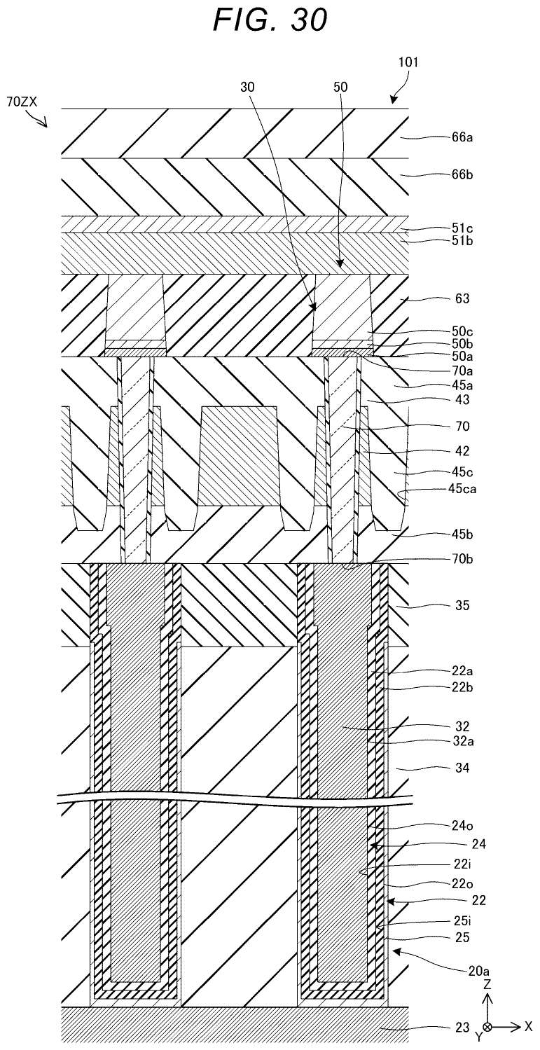

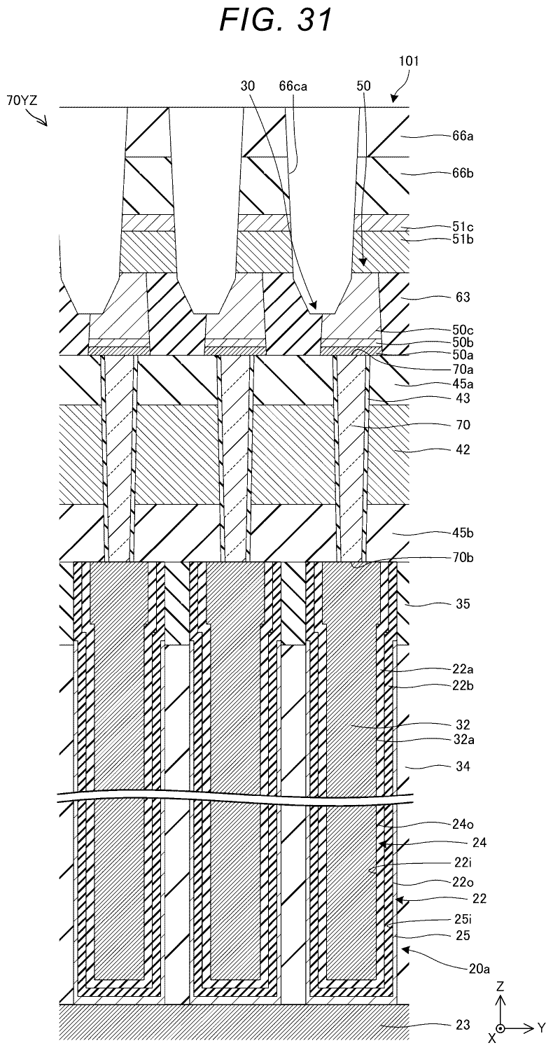

FIG. 30 shows a detailed cross-sectional view of a modification example of the semiconductor storage device 101 as seen in the cross section 70ZX provided in the oxide semiconductor layer 70, the cross section 70ZX parallel to the ZX plane. FIG. 31 shows a detailed cross-sectional view of the modification example of the semiconductor storage device 101 as seen in the cross section 70YZ provided in the oxide semiconductor layer 70, the cross section 70YZ parallel to the YZ plane.

As shown in FIGS. 30 and 31, the modification example of the semiconductor storage device 101 includes a capacitor 20a instead of the capacitor 20 as compared with the semiconductor storage device 101 shown in FIGS. 3 and 4.

The electrode 24 in the capacitor 20a does not include the conductive film 21 as compared with the electrode 24 in the capacitor 20. That is, the outer peripheral surface of the metal oxide layer 32 is the outer peripheral surface 24o of the electrode 24.

In this way, the step of depositing the conductive film 21 can be omitted by a structure in which the conductive film 21 is not provided. That is, the capacitor 20a can be manufactured by a simple step.

### Second Embodiment

A semiconductor storage device 102 according to a second embodiment will be described. In the following second embodiment and later, the description of matters common to the first embodiment will be omitted, and only different points will be described. In particular, the same effects of the same structures will not be successively described for each embodiment.

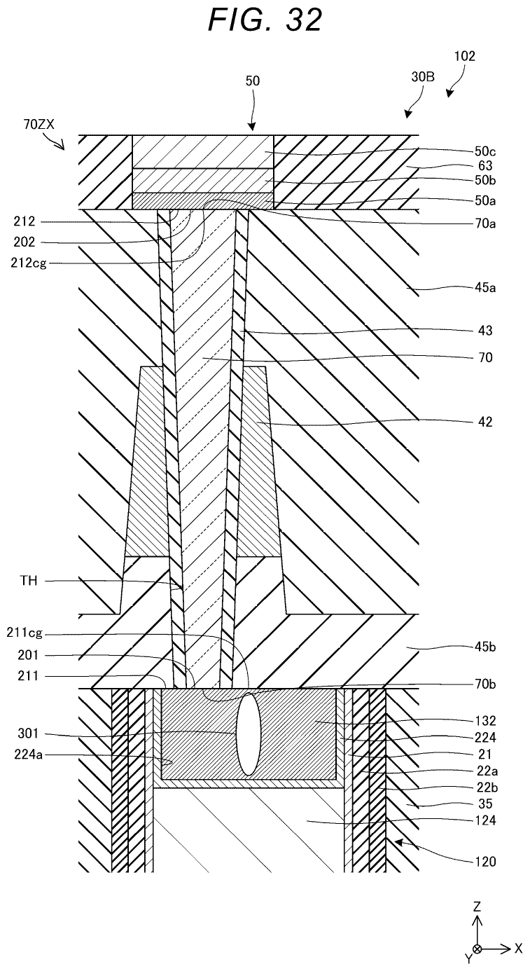

FIG. 32 shows a cross-sectional view of the semiconductor storage device 102 as seen in the cross section 70ZX provided in the oxide semiconductor layer 70, the cross section 70ZX parallel to the ZX plane.

As shown in FIG. 32, the semiconductor storage device 102 according to the second embodiment includes a semiconductor device 30B and the capacitor 120 instead of the semiconductor device 30 and the capacitor 20 as compared with the semiconductor storage device 101 shown in FIGS. 3 and 4.

The capacitor 120 includes the electrode 124, the metal oxide layer 132, and the barrier metal layer 224 instead of the metal oxide layer 32 as compared with the capacitor 20.

FIG. 33 is a plan view of a capacitor 120 as viewed from an upper side. As shown in FIGS. 32 and 33, in the semiconductor device 30B, the barrier metal layer 224 forms a recess 224a recessed on the lower side.

Specifically, the barrier metal layer 224 has a cup shape that is open on the upper side. The lower surface of the barrier metal layer 224 is in contact with the upper surface of the electrode 124. The side surface of the barrier metal layer 224 is in contact with the inner peripheral surface on the upper side of the conductive film 21.

The metal oxide layer 132 is buried in the recess 224a. The respective upper end portions of the insulating layer 35, the insulating film 22b, the insulating film 22a, the conductive film 21, the barrier metal layer 224, and the metal oxide layer 132 are aligned in the Z direction.

In addition, the metal oxide layer 132 is connected to the lower end 70b of the oxide semiconductor layer 70 and contains a second oxide conductive material. In the present embodiment, an upper surface 211 of the metal oxide layer 132 is in contact with the lower end 70b of the oxide semiconductor layer 70.

A contact portion 201 between the metal oxide layer 132 and the oxide semiconductor layer 70 is substantially circular. The metal oxide layer 132 is a cylinder having a center axis extending in the up-down direction.

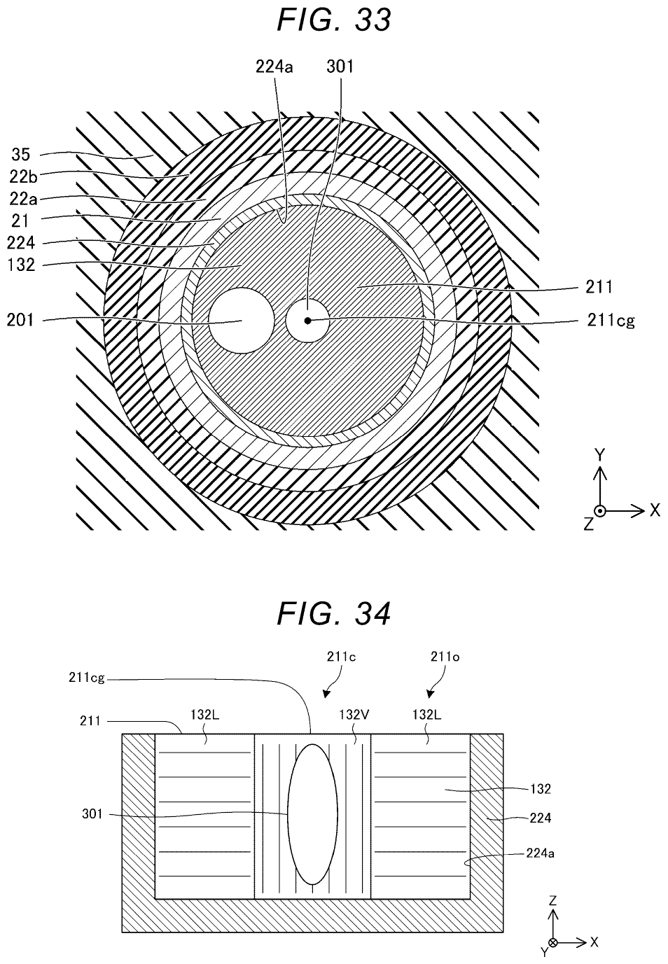

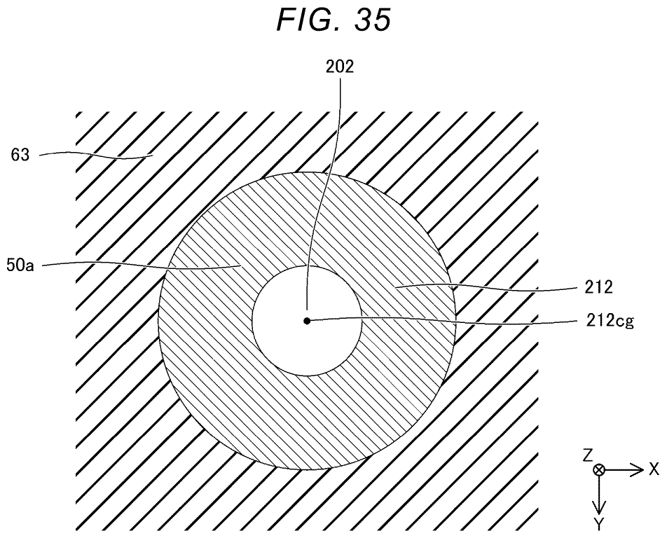

FIG. 34 is a schematic view illustrating a seam 301. As shown in FIGS. 32 to 34, the metal oxide layer 132 includes the seam 301. A center of gravity 211cg of the upper surface 211 of the metal oxide layer 132 and the seam 301 overlap each other when the metal oxide layer 132 is viewed in the up-down direction.

For example, when ITO is filled in the recess 224a by a sputtering method, the ITO may be filled in an outer peripheral portion 211o close to the side surface of the recess 224a, but the filling may be insufficient in a center portion 211c that is separated from the side surface and close to the center of gravity 211cg.

The seam 301 is a cavity that is not filled with ITO. In the present embodiment, the seam 301 has a spindle shape long in the up-down direction.

In addition, the metal oxide layer 132 filled in the recess 224a includes a lateral orientation portion 132L and a vertical orientation portion 132V. The lateral orientation portion 132L is close to the side surface of the recess 224a, and ITO is oriented along a plane parallel to the XY plane. The vertical orientation portion 132V is positioned closer to the side of the center of gravity 211cg than the lateral orientation portion 132L, and ITO is oriented along an axis parallel to the Z-axis.

The contact portion 201 between the oxide semiconductor layer 70 and the metal oxide layer 32 is not in contact with the seam 301 provided in the metal oxide layer 32.

When the metal oxide layer 132 is viewed in the up-down direction, the contact portion 201 is separated from the center of gravity 211cg. Preferably, when the metal oxide layer 132 is viewed in the up-down direction, the contact portion 201 and the seam 301 do not overlap each other.

In addition, the contact portion 201 is closer to the outer periphery of the metal oxide layer 132 than the center of gravity 211cg. Specifically, when the metal oxide layer 132 is viewed in the up-down direction, the distance between the contact portion 201 and the outer periphery of the metal oxide layer 132 is shorter than the distance between the contact portion 201 and the center of gravity 211cg.

FIG. 35 is a plan view of the metal oxide layer 50a as viewed from a lower side. As shown in FIGS. 32 and 35, when the metal oxide layer 50a is viewed in the up-down direction, a contact portion 202 between the oxide semiconductor layer 70 and the metal oxide layer 50a overlaps the center of gravity 212cg of the lower surface 212 of the metal oxide layer 50a.

The contact portion 202 may not overlap the center of gravity 212cg. In this case, preferably, the contact portion 202 is closer to the center of gravity 212cg than the outer periphery of the metal oxide layer 50a. Specifically, when the metal oxide layer 50a is viewed in the up-down direction, the distance between the contact portion 202 and the center of gravity 212cg is shorter than the distance between the contact portion 202 and the outer periphery of the metal oxide layer 50a.

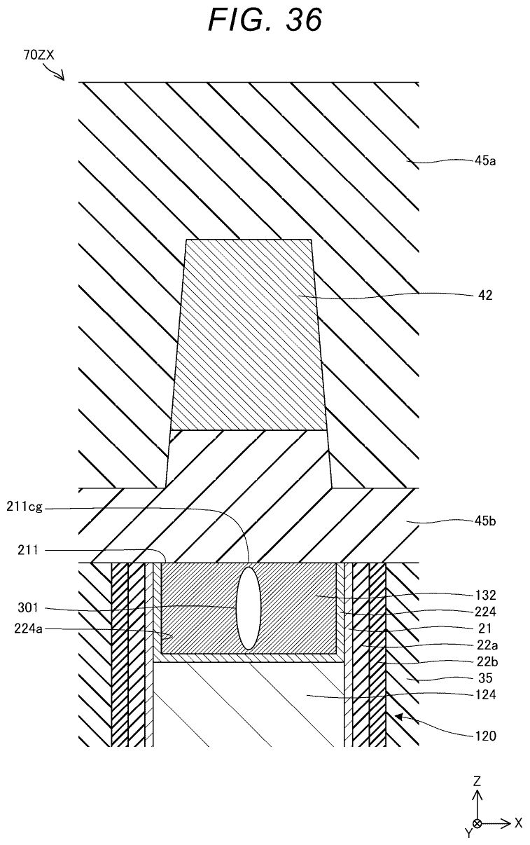

Comparative Example FIGS. 36 to 40 are cross-sectional views parallel to the ZX plane, showing a manufacturing process of a semiconductor device according to a comparative example.

First, as shown in FIG. 36, the seam 301 is formed in the metal oxide layer 132. The seam 301 overlaps the center of gravity 211cg when the metal oxide layer 132 is viewed in the up-down direction.

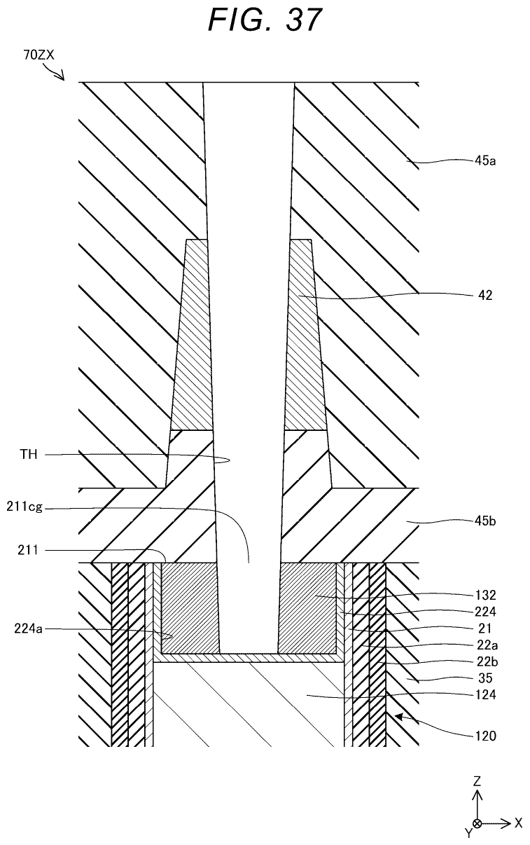

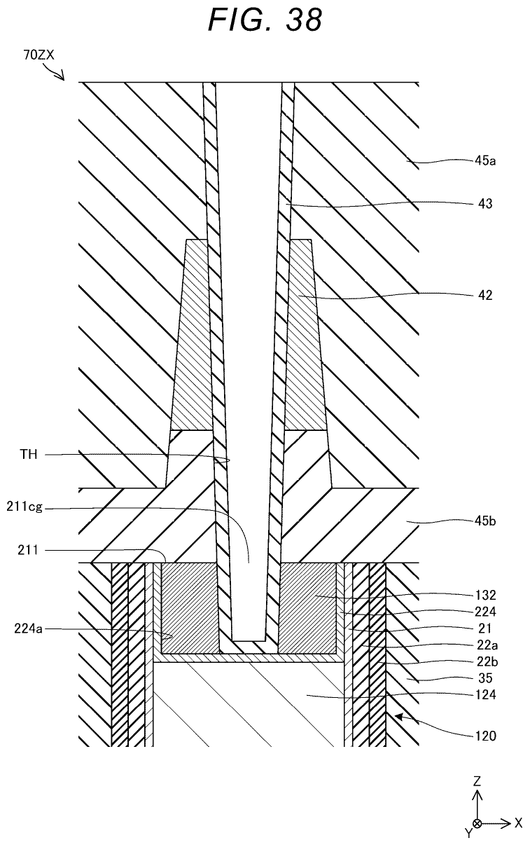

Next, as shown in FIG. 37, the transistor hole TH is formed by reactive ion etching. Meanwhile, when the transistor hole TH is formed such that the bottom portion of the transistor hole TH overlaps the center of gravity 211cg, the transistor hole TH may penetrate the metal oxide layer 132 since the seam 301 is present. In this case, the metal oxide layer 132 is exposed on the side wall of the transistor hole TH.

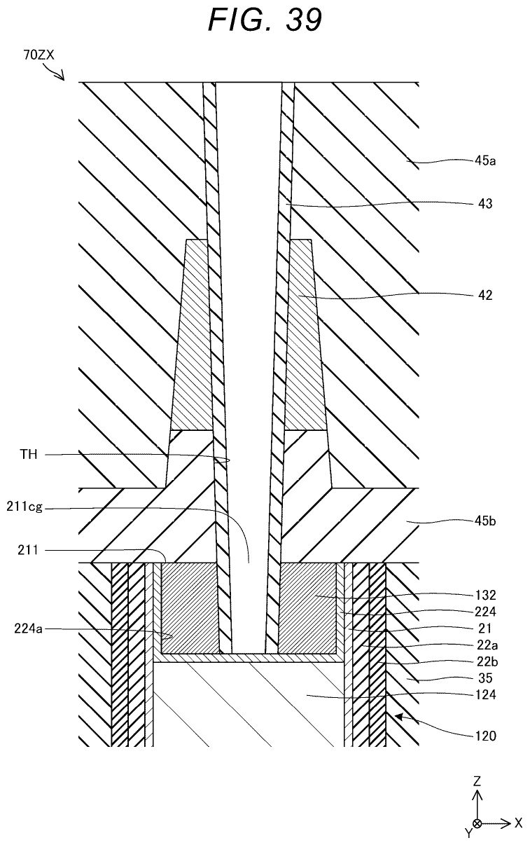

Next, as shown in FIG. 38, the gate insulating film 43 covers the inner surface of the transistor hole TH. Meanwhile, the temperature of the metal oxide layer 132 may rise due to the heat applied when the gate insulating film 43 is formed, and the metal oxide layer 132 may disappear.

Next, as shown in FIG. 39, the gate insulating film 43 at the bottom portion of the transistor hole TH is etched by reactive ion etching. Meanwhile, since the transistor hole TH has a tapered shape, the area of the bottom portion of the transistor hole TH is small, and it is difficult to etch the gate insulating film 43.

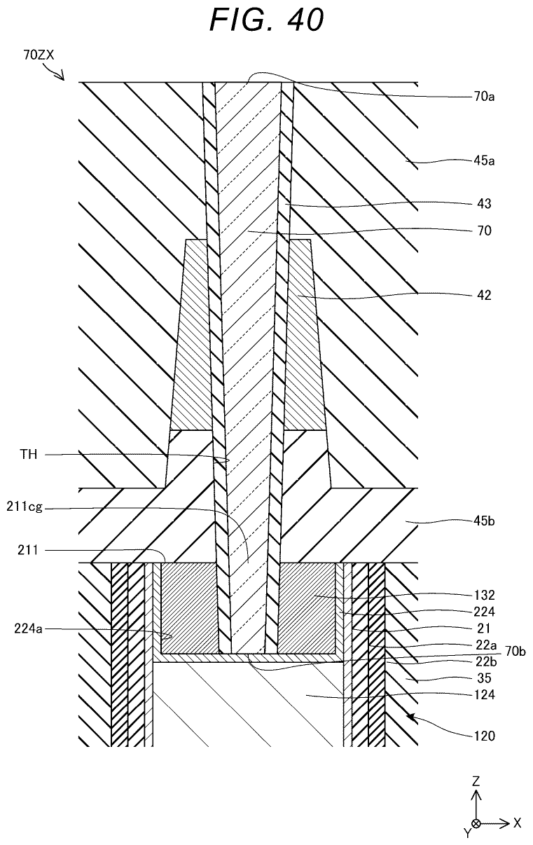

Next, as shown in FIG. 40, the oxide semiconductor layer 70 is formed in the transistor hole TH. Meanwhile, since the transistor hole TH has a tapered shape, the contact area between the oxide semiconductor layer 70 and the conductive film 21 at the lower end 70b is reduced.

### Method of Manufacturing Semiconductor Storage Device 102

Hereinafter, a method of manufacturing the semiconductor storage device 102 according to the second embodiment will be described.

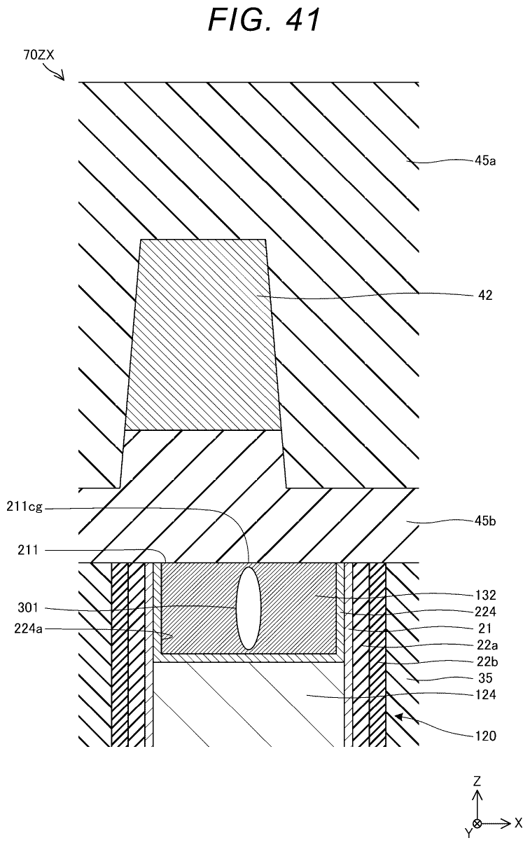

First, as shown in FIG. 41, the seam 301 is formed in the metal oxide layer 132. The seam 301 overlaps the center of gravity 211cg when the metal oxide layer 132 is viewed in the up-down direction.

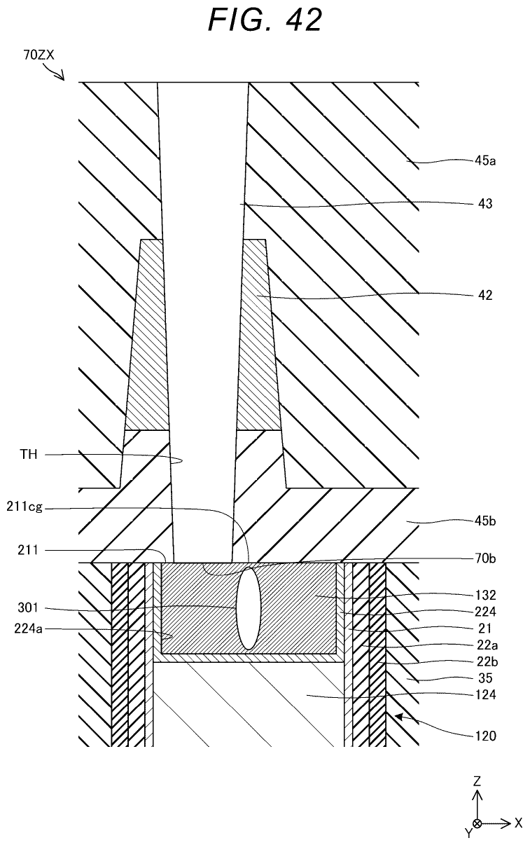

Next, as shown in FIG. 42, the transistor hole TH is formed by reactive ion etching such that the bottom portion of the transistor hole TH is positioned to be separated from the center of gravity 211cg. As a result, the seam 301, which is positioned directly below the center of gravity 211cg, can be prevented from being continuous with the transistor hole TH, and thus the transistor hole TH can be prevented from penetrating the metal oxide layer 132.

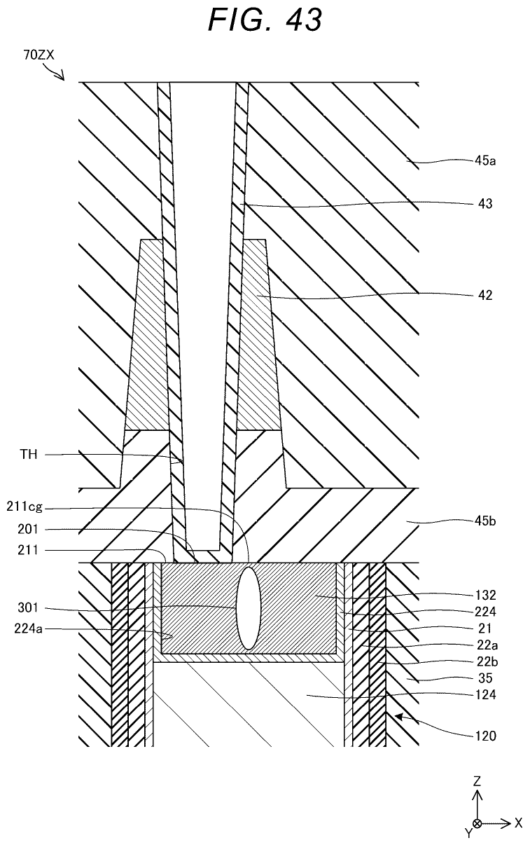

Next, as shown in FIG. 43, the gate insulating film 43 covers the inner surface of the transistor hole TH. In this case, unlike the case shown in FIG. 38, since the exposure of the metal oxide layer 132 is prevented at the bottom portion of the transistor hole TH, although the temperature of the metal oxide layer 132 rises due to the heat applied when the gate insulating film 43 is formed, the disappearance of the metal oxide layer 132 can be prevented.

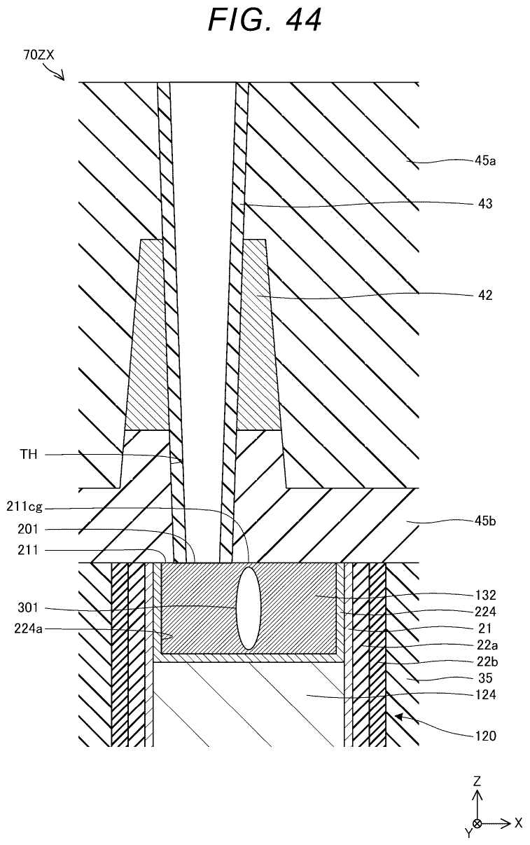

Next, as shown in FIG. 44, the gate insulating film 43 at the bottom portion of the transistor hole TH is etched by reactive ion etching. Unlike the case shown in FIG. 39, since the bottom portion of the transistor hole TH can be positioned further on the upper side, the area of the bottom portion of the transistor hole TH can be sufficiently allocated, and the etching of the gate insulating film 43 can be performed well.

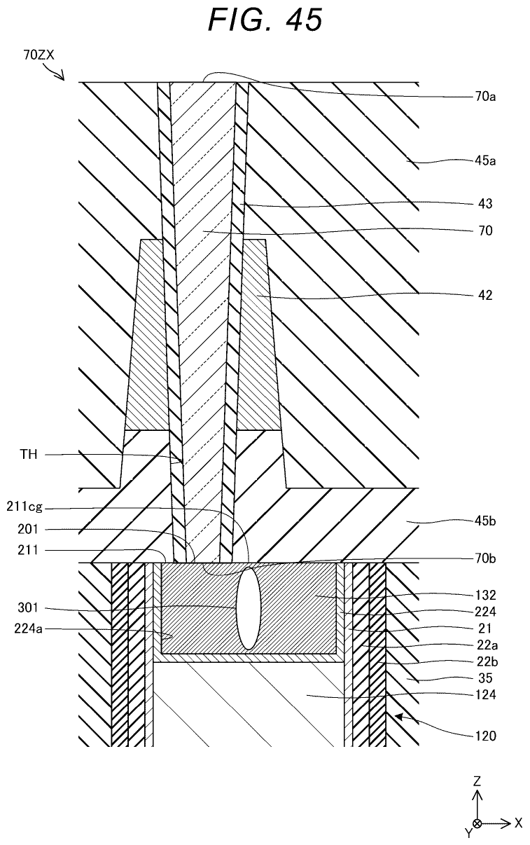

Next, as shown in FIG. 45, the oxide semiconductor layer 70 is formed in the transistor hole TH. Unlike the case shown in FIG. 40, since the lower end 70b of the oxide semiconductor layer 70 can be positioned further on the upper side, the area of the contact portion 201 can be sufficiently allocated.

### Modification Example of Shape of Seam

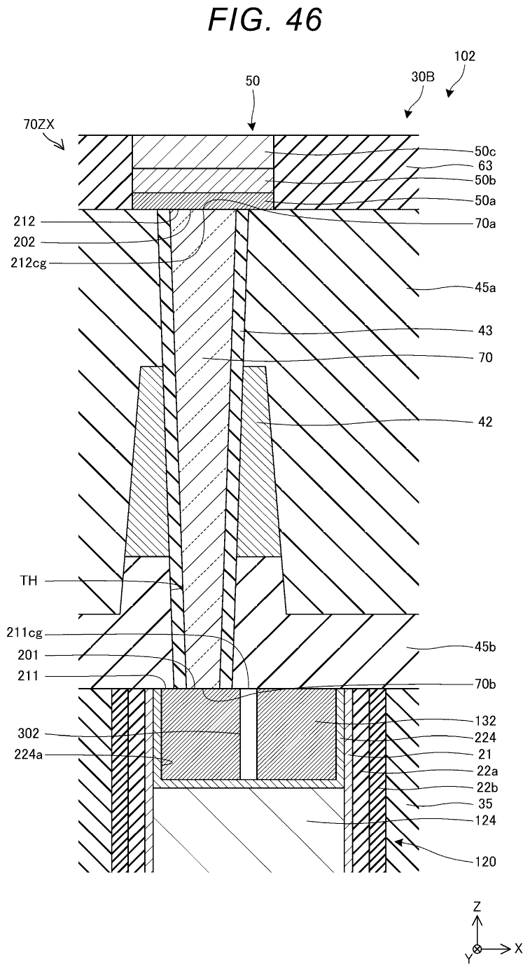

The shape of the seam 301 is not limited to a spindle shape (see FIG. 32), and may be another shape. For example, as shown in FIG. 46, the seam 302 may have a columnar shape long in the up-down direction and may have a structure in which the upper end and the lower end are exposed from the metal oxide layer 132. That is, the seam 302 penetrates the metal oxide layer 132.

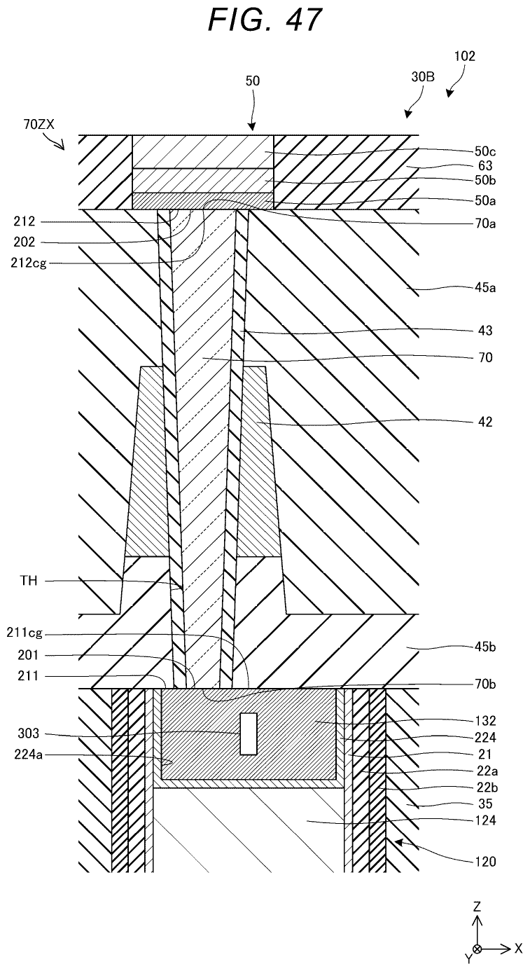

In addition, as shown in FIG. 47, a seam 303 is not limited to a structure in which the metal oxide layer 132 is penetrated similarly to the seam 302, and may have a columnar shape long in the up-down direction and to be buried in the metal oxide layer 132. In addition, the upper end or the lower end of the seam 303 may be exposed from the metal oxide layer 132.

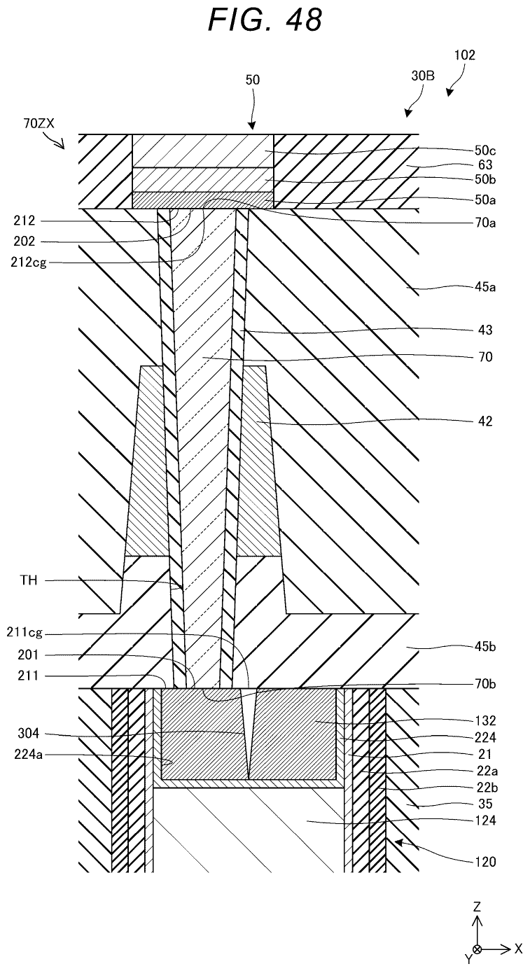

Further, as shown in FIG. 48, a seam 304 may have the upper end that is exposed from the metal oxide layer 132 and to have a tapered shape that narrows from the upper side toward the lower side.

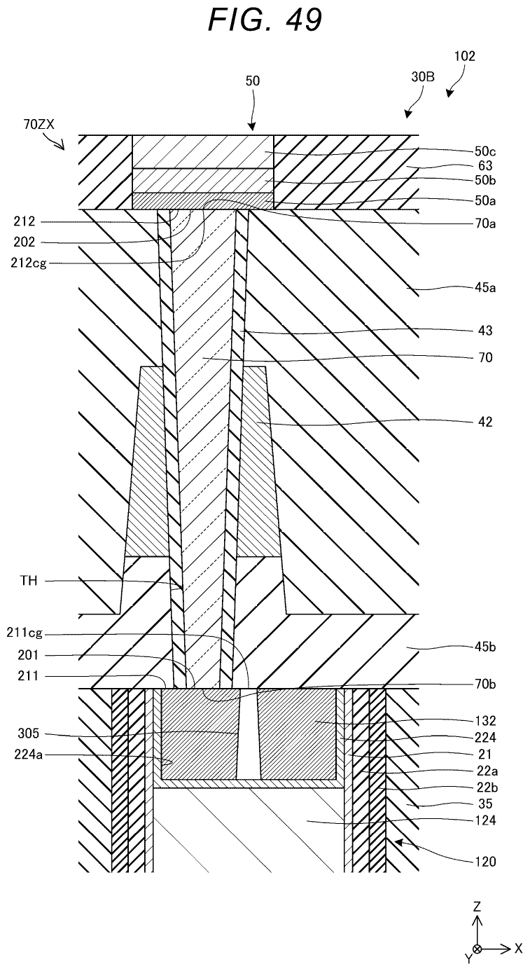

Further, as shown in FIG. 49, a seam 305 may have the upper end and the lower end that are exposed from the metal oxide layer 132 and to have a tapered shape that is enlarged in diameter from the upper side to the lower side.

The shapes of the seams 301 to 305 are substantially determined by the shape of the metal oxide layer 132, that is, the shape of the recess 224a. The shape of the metal oxide layer 132 in the adjacent capacitor 120 is often substantially the same. Consequently, the seam of substantially the same shape is often formed in the adjacent metal oxide layer 132.

In the semiconductor storage device 101, a structure in which the center axis 70d of the oxide semiconductor layer 70 and the center axis 32d of the metal oxide layer 32 are aligned is described, but the present disclosure is not limited thereto. The center axis 70d and the center axis 32d may be separated from each other in a direction intersecting the up-down direction. Specifically, the semiconductor device 30B may be provided on the upper side of the capacitor 20.

In addition, a structure in which the recess 224a is formed by the barrier metal layer 224 has been described in the capacitor 120, but the present disclosure is not limited thereto. At least a portion of the recess 224a may be formed by another electrode or an insulating film.

In addition, in the semiconductor storage device 102, a structure in which any of the seams 301 to 305 of the metal oxide layer 132 is provided is described, but the present disclosure is not limited thereto. The metal oxide layer 132 may have a structure that does not include the seams 301 to 305. Although the metal oxide layer 132 includes any of the seams 301 to 305, the semiconductor storage device 102 exhibits excellent electrical characteristics, so that it goes without saying that the semiconductor storage device 102 exhibits excellent electrical characteristics in a case where the metal oxide layer 132 does not include the seams 301 to 305.

(a) The semiconductor device further includes an insulating film or an electrode in which at least a portion of a recess is formed, a second electrode is buried in the recess, and, when the second electrode is viewed in an up-down direction, the first contact portion does not overlap the seam.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
an oxide semiconductor that extends in a first direction;
an insulating film on a side surface of the oxide semiconductor;
a gate electrode that faces the insulating film;
a first electrode that includes a first conductor which contains a first oxide conductive material and is connected to an upper end of the oxide semiconductor;
a second electrode that extends in the first direction and includes a second conductor containing a second oxide conductive material and connected to a lower end of the oxide semiconductor;
a dielectric layer on an outer peripheral surface of the second electrode; and
a third electrode on an outer peripheral surface of the dielectric layer, wherein
the second conductor has a first surface that faces an inner peripheral surface of the third electrode with the dielectric layer interposed therebetween.

2. The semiconductor storage device according to claim 1, wherein
the second electrode includes a third conductor facing an inner peripheral surface of the dielectric layer and containing titanium and nitrogen.

3. The semiconductor storage device according to claim 1, wherein
the second oxide conductive material contains at least one of indium, zinc, tin, iridium, ruthenium, titanium, or tungsten, and oxygen.

4. The semiconductor storage device according to claim 1, wherein
the second conductor has a columnar shape having a first center axis parallel to the first direction, and
the oxide semiconductor has a columnar shape having a second center axis parallel to the first center axis.

5. The semiconductor storage device according to claim 4, wherein
a diameter of a first portion of the second conductor is greater than a diameter of a second portion of the second conductor, the first portion being closer to the lower end of the oxide semiconductor than the second portion.

6. The semiconductor storage device according to claim 5, wherein
a diameter of a first portion of the second electrode is greater than a diameter of a second portion of the second electrode, the first portion being closer to the lower end of the oxide semiconductor than the second portion.

7. The semiconductor storage device according to claim 6, wherein
a lower end of the first portion of the second conductor is closer to the lower end of the oxide semiconductor than a lower end of the first portion of the second electrode.

8. The semiconductor storage device according to claim 5, wherein
a step exists between the first and second portions of the second conductor.

9. The semiconductor storage device according to claim 1, wherein
the first and second oxide conductive material are same.

10. The semiconductor storage device according to claim 1, further comprising:
an insulating layer on an outer peripheral surface of the third electrode.

11. A semiconductor device comprising:
an oxide semiconductor that extends in a first direction;
an insulating film that faces a side surface of the oxide semiconductor;
a gate electrode that faces the insulating film;
a first electrode that contains a first oxide conductive material and is connected to an upper end of the oxide semiconductor; and
a second electrode that contains a second oxide conductive material, extends in the first direction, is connected to a lower end of the oxide semiconductor, and includes an internal cavity, wherein
a first contact surface of the oxide semiconductor that contacts the second electrode does not overlap the cavity when viewed from the first direction.

12. The semiconductor device according to claim 11, further comprising:
an insulating film or an electrode having a recess, wherein
the second electrode is in the recess.

13. The semiconductor device according to claim 11, wherein
when viewed from the first direction, a center of gravity of an upper surface of the second electrode overlaps the cavity.

14. The semiconductor device according to claim 11, further comprising:
an insulating film or an electrode having a recess, wherein
the second electrode is in the recess, and
when viewed from the first direction, the first contact surface is shifted from a center of gravity of an upper surface of the second electrode.

15. The semiconductor device according to claim 11, wherein
the oxide semiconductor contains at least one of indium, gallium, zinc, tin, aluminum, iridium, ruthenium, or titanium, and oxygen.

16. The semiconductor device according to claim 11, wherein
the second oxide conductive material contains at least one of indium, zinc, tin, iridium, ruthenium, titanium, or tungsten, and oxygen.

17. The semiconductor device according to claim 11, wherein
a second contact surface of the oxide semiconductor that contacts the first electrode overlaps a center of gravity of a lower surface of the first electrode.

18. A semiconductor storage device comprising:
the semiconductor device according to claim 11;
a first capacitor electrode that is connected to the second electrode;
a second capacitor electrode that faces the first capacitor electrode; and
a dielectric film between the first and second capacitor electrodes.

19. A semiconductor storage device comprising:
the semiconductor device according to claim 11;
a dielectric layer on an outer peripheral surface of the second electrode; and
a third electrode on an outer peripheral surface of the dielectric layer, wherein
the second electrode includes a conductor connected to the lower end of the oxide semiconductor and having a first surface that faces an inner peripheral surface of the third electrode with the dielectric layer interposed therebetween.

20. A semiconductor device comprising:
an oxide semiconductor that extends in a first direction;
an insulating film that faces a side surface of the oxide semiconductor;
a gate electrode that faces the insulating film;
a first electrode that contains a first oxide conductive material and is connected to an upper end of the oxide semiconductor; and
a second electrode that is connected to a lower end of the oxide semiconductor and contains a second oxide conductive material, wherein
a first contact surface of the oxide semiconductor that contacts the second electrode is shifted from a center of gravity of an upper surface of the second electrode.
